(19) United States
(12) Patent Application Publication
(10) Pub. No.: US 2026/0107418 A1
(43) Pub. Date: Apr. 16, 2026

(54) SCALABLE IN-ROW COOLANT DISTRIBUTION UNITS, AND RELATED SYSTEMS AND METHODS

(71) Applicant: CoolIT Systems, Inc., Calgary (CA)

(72) Inventors: Brandon Peterson, Calgary (CA); Patrick McGinn, Calgary (CA); Bradley Zakaib, Calgary (CA); Mitchel Van Hanegem, Calgary (CA); Seyed Kamaleddin Mostafavi Yazdi, Calgary (CA)

(21) Appl. No.: 18/913,918

(22) Filed: Oct. 11, 2024

Related U.S. Application Data
(63) Continuation of application No. 18/913,724, filed on Oct. 11, 2024, now abandoned.

(51) Int. Cl. H05K 7/20

(52) U.S. Cl. CPC H05K 7/20781; H05K 7/20836

(57) ABSTRACT

A modular coolant-distribution unit includes one or more coolant-distribution modules configured to urge a secondary coolant to circulate through a secondary fluid network. Each coolant-distribution module can include a heat exchanger that thermally couples the secondary coolant with a primary coolant circulating through a primary fluid network without allowing the coolants to mix. Each coolant-distribution module can be removably coupled with respective manifolds for supplying and collecting secondary coolant and primary coolant. A reservoir can also be coupled with the secondary fluid network side of each coolant-distribution module. The coolant-distribution modules can be operated in conjunction with each other to operation as a single unit, allowing the modular-coolant-distribution unit to operate as a single unit while also being scalable according to a desired cooling capacity.

### CROSS-REFERENCE TO RELATED APPLICATIONS

Pertinent disclosures include, by way of example, U.S. Pat. No. 9,052,252, issued Jun. 9, 2015, U.S. Pat. No. 9,496,200, issued Nov. 15, 2016, U.S. Pat. No. 10,364,809, issued Jul. 30, 2019, U.S. Pat. No. 10,365,667, issued Jul. 30, 2019, and U.S. Patent Application Publication No. 2023/0240053, published Jul. 27, 2023. Each foregoing reference is hereby incorporated in its entirety as if fully set forth herein, for all purposes.

### FIELD

This application and the subject matter disclosed herein (collectively referred to as the “disclosure”), generally concern heat-transfer systems, components, and methods, such as, for example, liquid-based heat-transfer systems. More particularly, but not exclusively, this disclosure pertains to systems, methods, and components for cooling electronics, though disclosed innovations may be used in a variety of other heat-transfer (heating or cooling, or both) applications.

### BACKGROUND INFORMATION

As cloud-based and other services grow, the number of networked computers and computing environments, including servers, has substantially increased and is expected to continue to grow. New generations of electronic components, such as, for example, memory components, microprocessors, graphics processors, application specific integrated circuits (ASICs), hard drives, and power electronics semiconductor devices, produce increasing amounts of heat when operating. In addition, electronic devices, such as, for example, servers, computers, game consoles, power electronics, communications and other networking devices, batteries, and so on, arrange electronic components in close proximity with each other. If the heat generated by operating such components is not removed from such devices at a sufficient rate, the components can overheat, decreasing their performance, reliability, or both, and in some cases such overheating can result in outright component damage or failure.

The prior art has addressed these challenges using air cooling, liquid cooling (e.g., involving liquid coolant, e.g., water, glycol, polyethylene glycol, etc.), or a combination thereof, to transfer and dissipate heat from electronic components to an ultimate heat sink, e.g., the atmosphere.

Conventional air cooling relies on natural convection or uses forced convection (e.g., a fan mounted near a heat producing component) to replace heated air with cooler ambient air around the component. Such air-cooling techniques can be supplemented with a conventional “heat sink,” which often is a plate of a thermally conductive material (e.g., aluminum or copper) placed in thermal contact with the heat-producing component. The heat sink can spread heat from the component to a larger area for dissipating heat to the surrounding air. Some heat sinks include “fins” to further increase the surface area available for heat transfer and thereby to improve the transfer of heat to the air. Some heat sinks include a fan to force air among the fins and are commonly referred to in the art as “active”heat sinks.

Liquid cooling improves cooling performance compared to air cooling techniques described above, as many liquids, e.g., water, have significantly better heat transfer capabilities than air. Two-phase cooling improves cooling still further compared to liquid cooling, as many fluids, e.g., water, can absorb significantly more energy over a narrow temperature range as the fluid transitions from its liquid phase to its gas phase.

FIG. 1 illustrates various components of a pumped liquid cooling loop 5, though FIG. 1 can apply also to a pumped two-phase cooling loop. The cooling loop 5 typically operates by (1) transferring heat, \dot{Q}ᵢₙ, from a heat-generating electronic component (not shown) to a cool liquid passing through a heat exchanger 1 (sometimes referred to in the art as a “cold plate” or a “heat sink”) placed in thermal contact with the heat-generating component, (2) transporting the heat absorbed by the liquid to a remote radiator 2, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) dissipating the heat, \dot{Q}ₒᵤₜ, from the remote radiator to another medium (e.g., air or facility water passing through a remote radiator), and (4) returning cooled liquid to the heat exchanger (or heat sink). Many heat exchangers for removing heat generated by such components have been proposed. As but one example, device-to-liquid heat exchangers have been proposed, as for example in U.S. patent application Ser. No. 12/189,476 and related patent applications, and in other patent applications, e.g., U.S. patent application Ser. No. 63/635,593, filed Apr. 17, 2024, U.S. application patent application Ser. No. 61/794,698, filed Mar. 15, 2013. Also, pumped two-phase cooling systems have been proposed, as for example in U.S. patent application Ser. No. 18/297,561, filed Apr. 7, 2023. Each of the foregoing disclosures is hereby incorporated by reference as fully as if recited herein in its entirety, for all purposes.

IBM also previously disclosed several liquid-based cooling systems that uniformly relied on cool facility liquid to receive heat generated during operation of various electronic components. See, M. J. Ellsworth, et al., The Evolution of Water Cooling for IPB Large Server Systems: Back to the Future, IEEE Publication (2008). CoolIT Systems, Inc. of Calgary, AB, Canada, developed another innovative liquid-cooling solution for rack-mounted and other servers disclosed in U.S. Pat. No. 9,496,200, issued Nov. 15, 2016, the contents of which are hereby incorporated in its entirety as if recited herein in full, for all purposes.

Conventional data centers have heretofore largely relied on air-cooling of electronic components, without any liquid or two-phase cooling. Such air-cooling systems have typically provided conditioned (e.g., cooled) air throughout the data center. Conventional air-cooled data centers have typically had a “cold aisle” and each row of racks adjacent the cold aisle, e.g., on opposed sides of the cold aisle, has their inlet face oriented toward the cold aisle, allowing fresh, cool air to be drawn into the servers and across the heat-generating electrical components. The next aisle over from each cold aisle (in both lateral directions) is typically a “hot aisle” to which heated air exhausts from the adjacent racks.

In general, heat generating components spaced from each other (e.g., a lower heat density) can be more easily cooled than the same components placed in close relation to each other (e.g., a higher heat density). Consequently, data centers have also compensated for increased power dissipation (corresponding to increased server performance) by increasing spacing between adjacent servers. Relatively larger spacing between adjacent servers reduces the number of servers in (and thus the computational capacity of) the data center compared to relatively smaller spacing between adjacent servers.

Accordingly, the cooling capacity of air moving through the data center can limit the number of servers in such a data center. As well, a given data center's cooling system can limit the extent to which the data center's computational capacity (which corresponds the number and type of servers it can house) can scale into the future.

As used herein, the term “server” generally refers to a computing device connected to a computing network and running software configured to receive requests (e.g., a request to access or to store a file, a request to provide computing resources, a request to connect to another client) from client computing devices also connected to the computing network. Such client computing devices can take the form of traditional personal computers, tablets, smartphones, smart watches, as well as any of a variety of known or hereafter developed smart devices, including but not limited to devices within the so-called “internet of things.”

The term “data center” loosely refers to a physical location housing one or more servers. In some instances, a data center can simply comprise an unobtrusive corner in a small office. In other instances, a data center can comprise several large, warehouse-sized buildings enclosing tens (or hundreds) of thousands of square feet and housing thousands of servers.

### SUMMARY

In some respects, concepts disclosed herein generally concern systems, methods, and devices to remove excess heat from servers and heat-generating components within such servers. More particularly, but not exclusively, some disclosed concepts pertain to liquid-cooling systems (and related components) that remove sufficient heat from servers and heat-generating components within such servers to allow them to be more densely installed in data centers than air-cooling and prior liquid-cooling systems allow. Some disclosed concepts pertain to heat-transfer systems (and related components) that can be modularly scaled to tailor the heat-transfer capacity of the system to the heat-transfer demand of a given data-center installation. As but one example, some disclosed concepts pertain to rack-mountable manifolds and rack-mountable coolant distribution units that can be added to or removed from an in-row rack to selectively increase or decrease, respectively, the cooling capacity of a secondary flow network passing a secondary coolant among a plurality of populated server racks. Each modular coolant distribution unit can include a liquid-to-liquid heat exchanger to facilitate heat transfer from a relatively warmer liquid circulating in the secondary flow network, e.g., received from a plurality of servers, to a relatively cooler liquid supplied by a data center facility, cooling the liquid in the secondary flow network as it passes through the heat exchanger and before it returns to the plurality of servers to absorb additional waste heat generated by the servers. In still further respects, some disclosed concepts pertain to systems, methods and controllers for selectively controlling one or more such modular coolant distribution units as an individual or group.

Principles disclosed herein are described by way of reference to liquid-based cooling systems, but such principles also can be applied to heat-transfer systems that involve fluids that undergo partial or total phase transition to take advantage of the energy stored in a fluid during phase transition, e.g., the so-called latent-heat of phase transition.

According to some aspects, a modular coolant-distribution unit includes a manifold configured to distribute a primary coolant among a plurality of primary-coolant supply outlets, and a manifold configured to distribute a secondary coolant among a plurality of secondary-coolant return outlets. The modular coolant-distribution unit can also define a plurality of bays. Each bay can be configured to removably receive a coolant-distribution module configured to fluidicly couple with a selected one or more of the plurality of primary-coolant supply outlets and to fluidicly couple with a selected one or more of the plurality of secondary-coolant return outlets.

Some embodiments of a modular coolant-distribution unit also include a coolant-distribution module. The coolant-distribution module can fluidicly couple with a selected one or more of the plurality of primary-coolant supply outlets. As well, the coolant-distribution module can fluidicly couple with a selected one or more of the plurality of secondary-coolant return outlets.

Further, the coolant-distribution module can also be configured to thermally couple the primary coolant with the secondary coolant. For example, some disclosed modular coolant-distribution units also include a liquid-to-liquid heat exchanger that thermally couples the primary coolant with the secondary coolant without allowing the primary coolant and the secondary coolant to mix with each other.

The coolant-distribution module can be a first coolant-distribution module, and the plurality of bays can include a first bay and a second bay. The modular coolant-distribution unit can also include a second coolant-distribution module. In some embodiments, the first coolant-distribution module or the second coolant-distribution module, or both, can be removably engaged with the first bay or the second bay, respectively.

In some embodiments, the first coolant-distribution module can be fluidicly coupled with a selected one or more of the plurality of primary-coolant supply outlets and fluidicly coupled with a selected one or more of the plurality of secondary-coolant return outlets. Similarly, the second coolant-distribution module can be fluidicly coupable with a selected other one or more of the plurality of primary-coolant supply outlets and fluidicly coupable with a selected other one or more of the plurality of secondary-coolant return outlets.

A modular coolant-distribution unit can include control logic configured to control operation of a plurality of coolant-distribution modules in concert with each other. In some embodimehts, the control logic can control the coolant-distribution modules when they are fluidicly coupled with or among the plurality of primary-coolant supply outlets and the plurality of secondary-coolant return outlets.

In some embodiments, the control logic is configured to harmonize an operational output parameter between or among each of the plurality of coolant-distribution modules. For example, the operational output parameter can be one or more of (1) a differential pressure provided to the secondary coolant by each of the plurality of coolant-distribution modules; (2) a speed of a pump corresponding to each of the plurality of coolant-distribution modules; or (3) a selected temperature measure of the primary coolant, the secondary coolant, or both.

Some modular coolant-distribution units also include a coolant-distribution module fluidicly coupled with a selected primary-coolant supply outlet and a selected secondary-coolant return outlet. The coolant-distribution module can also include a liquid-to-liquid heat exchanger that thermally couples the primary coolant with the secondary coolant without allowing the primary coolant and the secondary coolant to mix with each other.

Some modular coolant-distribution units also include a manifold configured to receive the primary coolant from among a plurality of primary-coolant return inlets. Some modular coolant-distribution units also include a manifold configured to receive the secondary coolant from among a plurality of secondary-coolant supply inlets. The coolant-distribution module can further be fluidicly coupled with a selected primary-coolant return inlet and fluidicly coupled with a selected secondary-coolant supply inlet.

The coolant-distribution module can be a first coolant-distribution module and the modular coolant-distribution unit can further include a second coolant-distribution module. The first coolant-distribution module can be removably installed in one of the bays. The second coolant-distribution module can be removably installed in another one of the bays. Some modular coolant-distribution units include control logic configured to so control operation of the first coolant-distribution module and the second coolant-distribution module as to harmonize an operational output parameter between the first coolant-distribution module and the second coolant-distribution module.

The first coolant-distribution module can include a pump configured to urge the secondary coolant through the first coolant-distribution module. The second coolant-distribution module can include a pump configured to urge the secondary coolant through the second coolant-distribution module. The operational output parameter can include one or more of (1) a differential pressure provided to the secondary coolant by each respective coolant-distribution module; (2) a speed of the pump within each of the first coolant-distribution module and the second coolant-distribution module; or (3) a selected temperature measure of the primary coolant, the secondary coolant, or both.

A modular coolant-distribution unit can also include a chassis so sized as to fit within a row of server racks cooled by the secondary coolant supplied to the server racks by the modular coolant-distribution unit.

The manifold configured to distribute a primary coolant can be mounted to the chassis.

The manifold configured to distribute the second coolant can be mounted to the chassis.

The chassis can be configured to mountably support each respective coolant-distribution module removably received by the plurality of bays.

According to another aspect, data centers are disclosed. A data center can include a primary fluid network configured to circulate a primary coolant therethrough. The primary fluid network can have a plurality of primary coolant-supply connections and a plurality of primary coolant return connections. The primary fluid network can include a heat exchanger configured to reject heat from a return flow of the primary coolant. A data center can also include plurality of modular coolant-distribution units. Each modular coolant-distribution unit can have a primary coolant supply connection fluidicly coupled with a corresponding primary coolant-supply connection of the primary fluid network. Each modular coolant-distribution unit can further have a primary coolant return connection fluidicly coupled with a corresponding primary coolant-return connection of the primary fluid network. In some data centers, each modular coolant-distribution unit among the plurality of modular coolant-distribution units also includes one or more removably installed coolant-distribution modules. Such a coolant-distribution module can be configured to operate in concert with one or more other coolant-distribution modules. Each coolant-distribution module can be configured to transfer heat from a secondary coolant to the primary coolant as the primary coolant and the secondary coolant flow through the respective coolant-distribution module. A modular coolant-distribution unit among the plurality of modular coolant-distribution units can also include a secondary coolant-return manifold configured to convey warm secondary coolant to each of the one or more coolant-distribution modules. A modular coolant-distribution unit among the plurality of modular coolant-distribution units can also include a secondary coolant-supply manifold configured to receive cool secondary coolant from each of the one or more coolant-distribution modules. A data center can also have a secondary fluid network that includes a plurality of rack-cooling nodes. In some embodiments, the secondary fluid network receives cool secondary coolant from one or more of the secondary coolant-supply manifolds and conveys warm secondary coolant to one or more of the secondary coolant-return manifolds.

Each rack-cooling node can include a plurality of server-cooling nodes.

Each server-cooling node can include at least one component-cooling node. Each component-cooling node can facilitate a transfer of heat from a heat-generating component to the secondary coolant.

The secondary fluid network can convey the secondary coolant heated by each heat-generating component to the corresponding modular coolant-distribution unit. The heated secondary coolant can reject heat to the primary coolant flowing through the respective modular coolant-distribution unit.

The heat exchanger of the primary fluid network can facilitate rejecting, from the primary coolant, heat transferred to the primary coolant from the secondary coolant in the modular coolant-distribution unit.

Also disclosed are associated methods, as well as tangible, non-transitory computer-readable media including computer executable instructions that, when executed, cause a computing environment to implement one or more methods disclosed herein. Digital signal processors embodied in software, firmware, or hardware and being suitable for implementing such instructions also are disclosed.

The foregoing and other features and advantages will become more apparent from the following detailed description, which proceeds with reference to the accompanying drawings.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 schematically illustrates a closed liquid cooling loop.

FIG. 2 illustrates a rack of servers cooled by a modular cooling system.

FIG. 3 illustrates a server and components thereof cooled by the modular cooling system in FIG. 2.

FIG. 4 schematically shows a coolant-distribution module that can be operated as a coolant-distribution unit.

FIG. 5 schematically shows a modular cooling system for a datacenter.

FIG. 6 schematically shows a coolant-distribution module suitable for being incorporated in a module coolant-distribution unit, as in FIGS. 7 and 8.

FIG. 7 schematically shows a modular coolant-distribution unit including a plurality of coolant-distribution modules as in FIG. 6.

FIG. 8 is a photograph of a working embodiment of a modular coolant-distribution unit as in FIG. 7.

FIG. 9 schematically shows a modular coolant-distribution unit as in FIGS. 7 and 8 with several coolant-distribution modules removed.

FIG. 10 shows a method for operating a modular coolant-distribution unit that includes a plurality of coolant-distribution modules.

FIG. 11 schematically shows a plurality of coolant-distribution units as in FIG. 7 coupling a corresponding plurality of secondary fluid networks with a primary fluid network.

FIG. 12 schematically shows a genera-purpose computing environment.

### DETAILED DESCRIPTION

The following describes various principles related to liquid-cooling systems for data centers. For example, certain aspects of disclosed principles pertain to modular coolant distribution units and, more particularly but not exclusively, to modular, or scalable, in-row coolant distribution units suitable to be installed within a row of server racks, or otherwise among a plurality of server racks. That said, descriptions herein of specific apparatus configurations and combinations of method acts are but particular examples of contemplated systems chosen as being convenient illustrative examples of disclosed principles. One or more of the disclosed principles can be incorporated in various other systems to achieve any of a variety of corresponding system characteristics.

Thus, systems having attributes that are different from those specific examples discussed herein can embody one or more presently disclosed principles, and can be used in applications not described herein in detail. Accordingly, such alternative embodiments also fall within the scope of this disclosure.

### I. Overview

A data center can house any desired number of servers, each of which having a variety of heat-generating electronic components that need to be maintained at or below an upper temperature threshold. In some data centers, the servers are distributed among a plurality of racks and the racks are arranged throughout the data center in a desired fashion, often in rows of racks with aisles running between adjacent rows of racks. And, although a typical server rack of the type used in a data center can accommodate 42 individual servers, some server racks can accommodate more or fewer individual servers. Further, some server racks might not be fully populated regardless of their capacity. And, a given data center may change in scale over time, both in terms of the number of servers (and thus racks) that require cooling and in terms of heat load per server (or per rack) that needs to be removed from the servers. Disclosed cooling systems are backward compatible to many existing data centers, allowing them to be easily retrofitted to incorporate disclosed liquid cooling systems. Further, disclosed cooling systems can provide scalable cooling capacity that can be easily upgraded to meet future cooling loads. Thus, disclosed systems can be upfitted in the future, e.g., when increased cooling capacity is needed, as opposed to most current systems that require installing excess cooling capacity today to meet the anticipated cooling loads of tomorrow.

### II. A Liquid Cooling Archicture

Although air-cooled data center designs remain dominant across the industry, cooling systems that incorporate presently disclosed principles of modularity and scalability can deliver substantial cooling improvements over traditional air-cooling techniques while compatible with existing data center infrastructure and remaining flexible to adapt to future cooling demands. Thus, disclosed principles enable the use, today and into the future, of much higher-performance servers (which can generate substantially more heat compared to conventional servers) than conventional cooling systems can provide.

For example, a secondary liquid cooling loop (sometimes referred to in the art as a “secondary flow network” or “SFN”) can distribute secondary coolant among a group of servers (e.g., among servers mounted in one rack or across a plurality of racks). As the coolant passes through each server, it can absorb heat generated by one or more components therein. The heated coolant can be collected from each group of servers and passed through a heat exchanger to reject the absorbed heat. For example, a primary cooling loop (sometimes referred to in the art as a “primary fluid network” or “PFN”) in a data center can absorb the heat from the secondary coolant and reject the absorbed heat to an ultimate heat sink, e.g., atmosphere or ground.

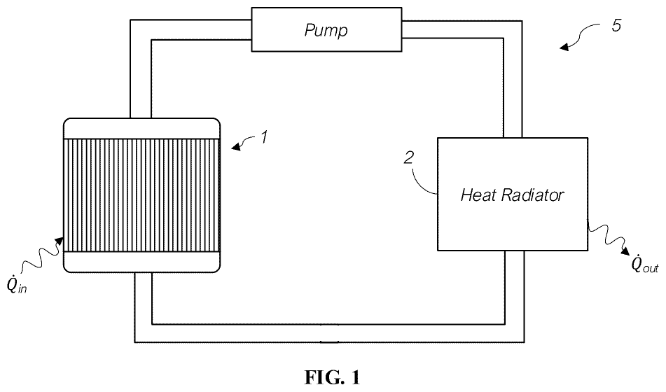

The loop shown in FIG. 1 can be considered as conceptually illustrating a SFN as opposed to a cooling loop for cooling a single CPU or other single-point heat source, as exists in the prior art. In context of an SFN, for example, the heat sink 1 can schematically depict or represent a plurality of heat sinks that transfer heat from a corresponding plurality of processing units (or other heat sources) to a liquid coolant circulating through the liquid cooling loop 5. Similarly, the radiator 2 can schematically depict or represent one or more radiators that reject the absorbed heat directly to air. Alternatively, the radiator 2 can schematically depict or represent one or more other types of heat exchangers that reject the absorbed heat to another medium, e.g., to another liquid coolant (e.g., circulating through a data center's PFN, or through another, intermediary liquid-cooling loop). In the case of transferring heat to another liquid coolant, the radiator 2 is understood to conceptually represent a liquid-to-liquid heat exchanger.

Alternatively, the loop shown in FIG. 1 can be considered to conceptually illustrate a PFN as opposed to an SFN or a cooling loop for cooling a single-point heat source. In context a PFN, for example, the heat sink 1 schematically depicts or represents one or more heat exchangers that transfer heat from another fluid to the coolant circulating through the PFN. For example, when the PFN absorbs heat from an SFN, the heat sink 1 shown in FIG. 1 depicts a liquid-to-liquid heat exchanger configured to transfer heat from the SFN to the PFN. (This would be the same heat exchanger depicted by the radiator 2 when FIG. 1 is considered to represent an SFN.) Alternatively, the other medium can be air within the data center that has been used to cool a plurality of servers. In this context, the heat sink 5 schematically depicts or represents one or more air-to-liquid heat exchangers. In either PFN context (or in systems that combine liquid and air cooling of servers), the radiator 2 is understood to schematically depict or represent a cooling tower or other conditioning unit that rejects heat from the coolant circulating through the PFN to an ultimate heat sink.

As explained more fully below, aspects of disclosed principles pertain to providing a scalable thermal interface between an SFN (e.g., an SFN used to directly cool one or more heat sources among a plurality of servers) and a PFN suited to absorb heat from an SFN. Some disclosed cooling systems are modular in nature, which allows them to adjust their cooling capacity up or down to facilitate cooling of data centers across a wide variety of thermal loads. Moreover, some disclosed cooling systems can be easily retrofitted to add or remove cooling capacity in correspondence with a data center's growth (or other change) in thermal load. Further, such modularity allows technicians to maintain and repair such cooling systems while keeping the cooling system operational, e.g., without interrupting operation of the servers being cooled by the cooling system. And still further, some disclosed cooling systems can be retrofitted to currently installed infrastructure systems in existing data centers with only limited modifications to the already installed infrastructure. For example, some disclosed heat exchangers (and their corresponding components) between an SFN and a PFN are so sized as to fit within the footprint of a commonly available server rack, e.g., a standard 42U rack. For example, some modular coolant distribution units are so sized as to fit within the footprint of a commonly available server rack, e.g., a standard 42U rack.

### III. Modular Heat-Transfer Systems

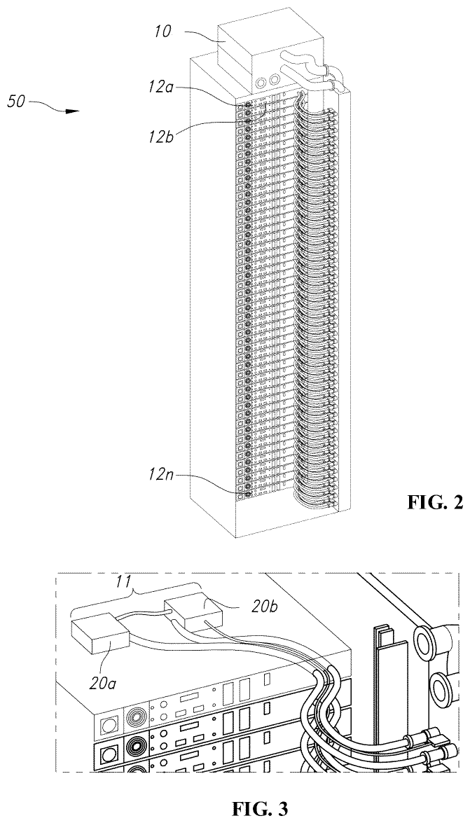

By way of example, FIG. 2 shows an array 50 of independently operable servers 12a, 12b . . . 12n mounted in a rack, or chassis, together with aspects of a modular heat-transfer system for cooling the servers. In FIG. 2, each server 12a-n contains one or more corresponding electronic components that dissipate heat while operating. A heat-transfer (e.g., cooling) system (and more particularly, an SFN) can circulate a (secondary) liquid coolant among the servers to collect heat from heat sources within the servers and carry the heat to a suitable heat exchanger that acts a sink for the absorbed heat. For example, a liquid-to-liquid heat exchanger can facilitate rejection of the heat from the coolant in an SFN to a facility liquid (e.g., in a PFN), atmospheric air, and/or air in a conditioned room containing the rack of servers. Such an arrangement for cooling rack mounted servers is described in further detail in U.S. Pat. No. 9,496,200.

In FIG. 2, an SFN distributes a secondary coolant among the servers to absorb heat from the heat sources within the server and to carry the absorbed heat to a liquid-to-liquid heat exchanger, where the heat can be rejected to a PFN. An SFN for a modular cooling system as shown in FIGS. 2 and 3 can provide at least one cooling node for each server. As used herein, the term “node” means an identifiable component (or an identifiable group of components) within a system and the term “cooling node” means an identifiable component (or an identifiable group of components) that absorb(s) heat from an external source (e.g., that cools the external heat source).

For example, in context of a modular heat-transfer system for cooling one rack of 42 individual servers, as with the system shown in FIG. 2, the cooling system can provide 42 server-cooling nodes, with each server-cooling node corresponding to one of the 42 servers in the rack. The portion of the modular cooling system shown in FIG. 3 illustrates a server-cooling node 11 corresponding to one of the servers 12a-n.

In similar fashion, a given server-cooling node (or more than one of them, or all of them) can incorporate one or more component-cooling nodes. For example, if a given server has two electronic components (e.g., two processors) to be cooled by that server's server-cooling node, that server's server-cooling node can provide one component-cooling node for each electronic component to be cooled. As FIG. 3 shows, the server cooling node 11 provides a first component-cooling node 20a and a second component-cooling node 20b. The first component-cooling node 20a is thermally coupled with a first processor to transfer heat from the first processor to a liquid coolant passing through the first component-cooling node 20a. Similarly, the second component-cooling node 20b is thermally coupled with a second processor to transfer heat from the second processor to a liquid coolant passing through the second component-cooling node 20b. Representative component-cooling nodes are described in further detail in U.S. Pat. Nos. 8,746,330 and 9,453,691, each of which is hereby incorporated by reference in its entirety as if recited in full, for all purposes. The component-cooling nodes can be passive, as in the '330 Patent, or they can be active, e.g., include a pump, as in the '691 Patent.

FIGS. 2 and 3 also depict portions of an SFN, or a secondary coolant circuit, that conveys coolant to and from each server-cooling node (e.g., server-cooling node 11 in FIG. 3), as well as to and from each component-cooling node 20a, 20b. For example, the coolant-distribution unit 10 conveys cool coolant to a secondary flow network, or SFN and receives warmed coolant from the SFN. In FIG. 2, the SFN includes distribution manifold configured to distribute the cool secondary coolant of the SFN among the various server-cooling nodes, as well as a collection manifold configured to collect the warm secondary coolant of the SFN from the various server-cooling nodes. The SFN shown in FIGS. 2 and 3 provides a branch of a fluid circuit for each server 12a-n. Each branch of the illustrated SFN receives cool coolant from the distribution manifold and conveys the cool secondary coolant to the server-cooling node 11 where the secondary coolant absorbs heat. Further, each fluid-circuit branch conveys warm secondary coolant exiting from the server-cooling node 11 to the collection manifold, which returns the warmed coolant to the SFN side of the coolant-distribution unit 10. In the system shown in FIGS. 2 and 3, the fluid-circuit branch defining each server-cooling node is fluidically coupled in parallel with the fluid-circuit branches for each of the other server-cooling nodes.

But, within the fluid-circuit branch shown in FIG. 3, the component-cooling nodes 20a, 20b are fluidically coupled with each other in series. For example, in FIG. 3, the component cooling node 20a receives cool secondary coolant arriving from the coolant distribution manifold and heats the secondary coolant with heat dissipated by the first processor. After exiting the first component-cooling node 20a, the secondary coolant heated by the first processor enters the second component-cooling node 20b, where the secondary coolant is further heated by the second processor before returning to the SFN side of the coolant-distribution unit 10 by way of the collection manifold. Although not shown in FIG. 3, the component-cooling nodes 20a, 20b can be fluidically coupled with each other in parallel, which each component-cooling node receiving secondary coolant from a corresponding further branch of the coolant circuit, or each directly from the distribution manifold.

As noted above, a modular cooling system as shown in FIG. 2 can include a coolant distribution unit configured to supply the various servers with cool secondary coolant by rejecting heat from the secondary coolant, which has been warmed by the servers, to a supply of cool facility, or primary, liquid coolant. FIG. 2 shows a rack-level embodiment of such a coolant-distribution unit 10. The coolant-distribution unit 10 incorporates a heat exchanger configured to transfer heat from a secondary coolant circulating through an SFN that extends among the servers in the rack to a primary coolant circulating through a PFN, a portion of which directs a primary coolant through a PFN side of the coolant-distribution unit. The SFN side of the coolant-distribution unit 10 can return the cooled secondary coolant to the servers (via the SFN) to collect further heat from the servers. The PFN side of the coolant-distribution unit can return heated coolant to the PFN for subsequent cooling and return of cool, primary coolant.

A coolant-distribution unit is sometimes referred to as a “coolant heat-exchange unit” when it incorporates a heat-exchanger to reject heat from the secondary coolant passing through the coolant-distribution unit. In the embodiment depicted in in FIG. 2, the coolant-distribution unit 10 can have at least one pump and can also incorporate a reservoir and other components, regardless of whether the coolant-distribution unit incorporates a heat exchanger.

IV. Another Modular Heat-Transfer System

Some large-scale and hyperscale data centers have significantly more servers than a single rack can accommodate. In fact, some large-scale and hyperscale data centers house thousands of servers distributed among many dozens of arrays of rack-mounted servers.

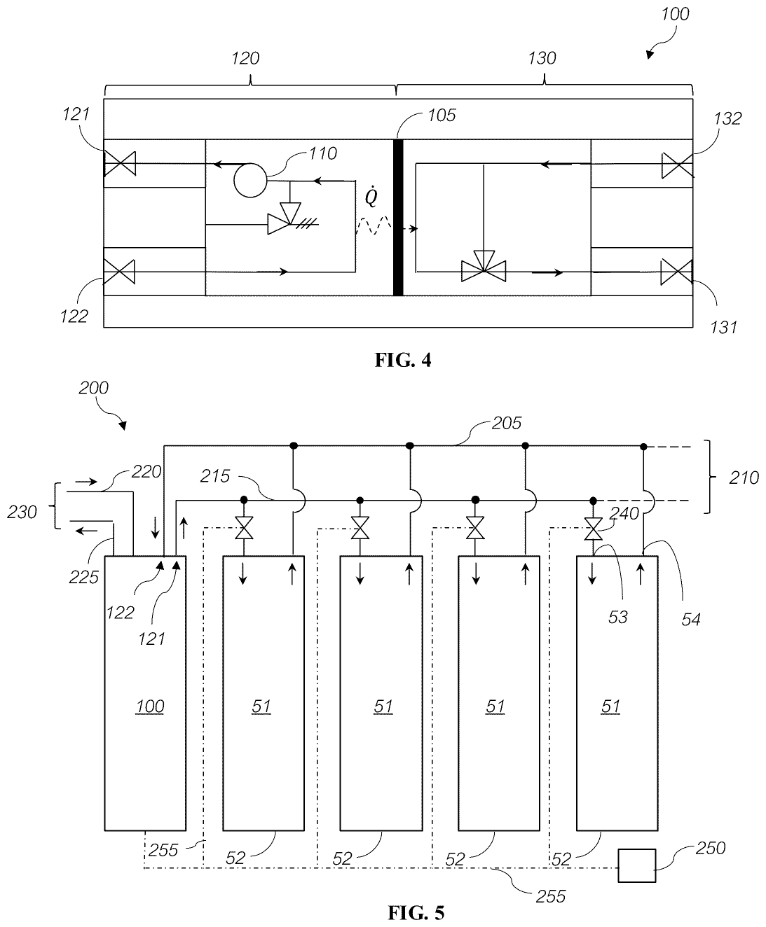

Referring now to FIGS. 4 and 5, embodiments of a modular heat-transfer system suitable for cooling a plurality of racks of servers (each being similar to the rack of servers shown in FIG. 2) will be described. As noted above, a coolant-distribution unit generally supplies an SFN with cool secondary coolant, and the SFN distributes the secondary coolant among the servers. As the secondary coolant passes through the servers, it absorbs heat from the heat sources within the servers. The SFN then collects the heated secondary coolant from among the servers and conveys it to a secondary coolant return port of the coolant-distribution unit.

FIG. 5 shows an embodiment of a modular heat-transfer system 200 configured to cool such a plurality of racks 52 of servers. The heat-transfer system 200 includes an off-rack (e.g., stand-alone, or “in-row”) coolant-distribution unit 100.

As depicted, the coolant-distribution unit 100 receives heated secondary coolant from a collection manifold 205 of an SFN 210 and delivers cool secondary coolant to a distribution manifold 215 the SFN for distribution among the plurality of rack-cooling nodes 51. The coolant-distribution unit 100 also receives cool primary coolant from a PFN supply 220 (e.g., facility liquid) and returns heated primary coolant to a PFN return 225.

Unlike the rack-mounted coolant-distribution unit 10 that facilitates cooling a single rack of servers 12a-n, a row-based coolant distribution unit can cool a plurality of rack-cooling nodes 51, each of which corresponding to a single rack 52 of servers. As depicted in FIGS. 4 and 5, the SFN 210 (FIG. 5) distributes the secondary coolant among the server-cooling nodes 51, each of which in turn further distributes the secondary coolant among the servers mounted therein in a manner similar to distribution of secondary coolant among the servers 12a-n shown in FIG. 2 as mounted in a single rack. For example, a single rack-cooling node 51 can provide cooling to each server-cooling node 11 (e.g., all 42 nodes) shown in FIG. 3, while omitting the on-rack coolant distribution unit 10 shown in FIG. 2. The depiction in FIG. 5 shows four rack-cooling nodes 51 within an SFN 210, despite that the system 200 can have more or fewer rack-cooling nodes 51 distributed throughout the illustrated SFN. This is depicted by the dashed lines extending to the right of and above the rack-cooling nodes 51 in FIG. 5.

In FIG. 5, each server rack 52 corresponding to a rack-level cooling node 51 contains an array of rack-mounted servers, e.g., similar to the array of rack-mounted servers shown in FIG. 2. However, unlike the heat-transfer system 50 shown in FIG. 2, which provides on-rack cooling to one array of rack-mounted servers, the heat-transfer system 200 shown in FIG. 5 provides cooling to a plurality of arrays of rack-mounted servers using a single SFN 210.

For example, as with the modular heat-transfer system shown in FIG. 2, each rack-level cooling node 51 can have 42 server-cooling nodes (e.g., analogous to server-cooling node 11), with each server-cooling node corresponding to one rack-mounted server. As with the rack of servers shown in FIG. 2, each rack of servers 52 in FIG. 5 can have more or fewer than 42 servers, and thus more or fewer than 42 server-cooling nodes. Further, each server-cooling node within each rack-level cooling node 210a-d can have one or more component cooling nodes (e.g., analogous to the component-level cooling nodes 20a, 20b in FIG. 3).

In FIGS. 4 and 5, the coolant-distribution unit 100 receives heated secondary coolant from a collection (or return) manifold 205 of an SFN 210 and delivers cool secondary coolant to a distribution (or supply) manifold 215 of the SFN 210 for distribution among the plurality of rack-cooling nodes 51. The coolant-distribution unit 100 also receives cool primary coolant from a PFN supply 220 and returns heated primary coolant to a PFN return 225.

As FIG. 4 shows, the liquid-to-liquid heat exchanger 105 rejects heat, \dot{Q}, from the coolant received at the SFN return 122 from the collection manifold 205 to cool facility coolant received from the facility supply 220. As the primary coolant passes through the heat exchanger 105, it absorbs the heat, \dot{Q}, and increases in temperature, eventually exiting the coolant-distribution unit 100 through the PFN return outlet 131 and passing to the facility return 225. After rejecting the heat, \dot{Q}, the now cooled secondary coolant enters a circulation pump 110. An outlet from the pump 110 conveys the secondary coolant to an SFN supply outlet 121, which fluidicly couples with the SFN supply manifold 215, allowing the cooled coolant to return to the several rack-cooling nodes 51.

Correspondingly, the PFN side 130 of the coolant-distribution unit 100 can deliver heated primary coolant to a PFN return outlet 131. The PFN return outlet 131 can couple with the PFN return 220 for subsequent cooling so that, once again, the PFN supply 225 can supply cooled primary coolant to the PFN supply inlet 132 of the coolant-distribution unit 100.

When a heat exchanger is included within the confines of a coolant-distribution unit, as in FIG. 4, the SFN side 120 of the coolant-distribution unit can receive the return flow of warm coolant carrying heat absorbed from the various cooling nodes 51 (or in context of the system shown in FIGS. 2 and 3, the server-cooling nodes corresponding to the servers 12a-n). As FIG. 4 shows, the coolant-distribution unit 100 can also connect to a facility supply of primary coolant, e.g., on a PFN side 130 of the coolant-distribution unit.

Referring now to FIG. 5, a liquid-to-liquid heat exchanger (present but not shown in FIG. 5, analogous to heat exchanger 105) can thermally couple the SFN 210 with the PFN 230, while keeping the secondary coolant in the SFN 210 physically isolated from the primary coolant in the PFN 230. Thus, the liquid-to-liquid heat exchanger can facilitate cooling of the secondary coolant as heat transfers from the relatively warmer secondary coolant passing through the SFN side 210 of the liquid-to-liquid heat exchanger to a relatively cooler primary coolant passing through the PFN side 230 of the liquid-to-liquid heat exchanger. The SFN side 210 of the coolant-distribution unit 200 can then, once again, deliver the cooled secondary coolant to a secondary supply outlet 121 (FIG. 5), which in turn can couple with the cooling nodes 51 of the SFN 210 where the secondary coolant can absorb further heat.

Each rack-cooling node 51 receives cool secondary coolant from the SFN supply manifold 215 and returns heated secondary coolant to the SFN return manifold 205. For example, each rack-cooling node 51 has a supply connection 53 with the SFN supply manifold 215 and a return connection 54 with the SFN return manifold 205.

The cooling capacity of a given cooling node (e.g., a rack-cooling node 51) depends on many parameters. But, in a general sense, the available cooling capacity corresponds to a temperature of secondary (or tertiary) coolant entering the cooling node, a permissible increase in coolant temperature as it passes through the cooling node, and a flow rate of coolant passing through the cooling node. With all else being equal, a cooling node with a higher mass-flow rate of secondary coolant passing through has a higher cooling capacity than it does with a lower mass-flow rate of coolant passing through. Accordingly, a cooling node that adequately cools a heat source (e.g., an electronic component, a server, or a rack of servers) that dissipates an upper threshold rate of heat will provide excess cooling to the heat source if the rate of heat generated by the source falls and the mass-flow rate of secondary coolant through the cooling node remains unchanged. Stated differently, as the rate of heat generated by a heat source falls, a mass-flow rate of secondary coolant through the corresponding cooling node can be reduced, or an incoming temperature of the secondary coolant can be increased, or both. Conversely, as the rate of heating increases, a mass-flow rate of secondary coolant through the corresponding cooling node can be increased, or an incoming temperature of the secondary coolant can be decreased, or both. In some embodiments, a controller can reduce a pump speed or partially close a valve, or both, to reduce a flow rate of secondary coolant available to a given cooling node (as when the rate of heat dissipation by the heat source falls). Similarly, the controller can increase a pump speed or partially (or wholly) open a valve, or both, to increase a flow rate of secondary coolant available to the cooling node, as when the rate of heating increases.

In the illustrated embodiment of the heat-transfer system 200, a variable-position, controllable valve 240 can be positioned at or between the supply connection 53 and the SFN supply manifold 215. Stated differently, the branch of the SFN coolant loop that conveys secondary coolant to and from each rack-cooling node 51 can have a flow-control valve 240 for adjusting a mass-flow rate of coolant that passes through each rack-cooling node 51. In other embodiments, one or more of the controllable valves 240 can be positioned at or between the SFN return manifold 205 and the return connection 54.

As with the cooling system 200 shown in FIG. 5, one or more server-cooling nodes (not shown in FIG. 5 but analogous to the server-cooling node 11 in FIG. 2) within one or more of the rack-cooling nodes 51 can also have a flow-control valve for adjusting a mass-flow rate of coolant that passes through the server-cooling node(s) within the rack-cooling node 51. Alternatively (or additionally), one or more server-cooling nodes among the rack-cooling nodes 51 can have one or more pumps. Such server-level valves and pumps can allow a cooling-system operator to tailor the cooling capacity delivered to each server-cooling node. Moreover, although not illustrated, one or more of the server-cooling nodes among the rack-cooling nodes 51 shown in FIG. 5 can include a rack-mounted coolant-distribution unit analogous to the coolant-distribution unit 10 shown in FIG. 2. In such embodiments, the secondary coolant distributed among the plurality of rack-cooling nodes 51 in FIG. 5 is analogous to the primary coolant described in connection with the system in FIGS. 2 and 3, and the secondary coolant distributed among the server-cooling nodes in FIGS. 2 and 3 can, for convenience, be considered a tertiary coolant in the system shown in FIG. 5. Regardless of the naming convention applied, a coolant passing through each server-cooling node (e.g., a tertiary coolant) can be returned to the on-rack coolant-distribution unit and cooled by the coolant (e.g., secondary coolant) passing among the plurality of rack-cooling nodes 51 in FIG. 5. Further, the secondary coolant distributed among the plurality of rack-cooling nodes 51 can thence be cooled by a coolant (e.g., a primary coolant) passing through the in-row coolant-distribution unit 100.

Referring still to FIG. 5, the heat-transfer system 200 also has a controller 250, together with one or more communication connections 255 (e.g., a logic bus) that communicatively couples the controller 250 with one or more sensors (not shown) as well as one or more flow-control devices (e.g., valves 240, pump 110). For example, based on information received from one or more sensors, the controller 250 can output a control signal to adjust operation of one or more flow-control devices. As an example of such adjustments, an output signal from the controller can cause a valve to change or to maintain its opening within a range from 0% open (e.g., closed) to 5% open (e.g., unobstructed). As another example, the control output signal can cause a pump to speed up, slow down, start, or stop operation. For example, the coolant-distribution unit 100 may have one or more pumps 110 hydraulically coupled with each other in parallel, in series, or a combination of parallel and series to provide suited to maintain stable operation over a wide range of pressure-drop and flow-rate conditions of the SFN 210. With such a coolant-distribution unit, the controller can adjust operation of one or more of the pumps 110 to deliver a target pressure head and flow rate to the SFN 210 of the cooling system 200.

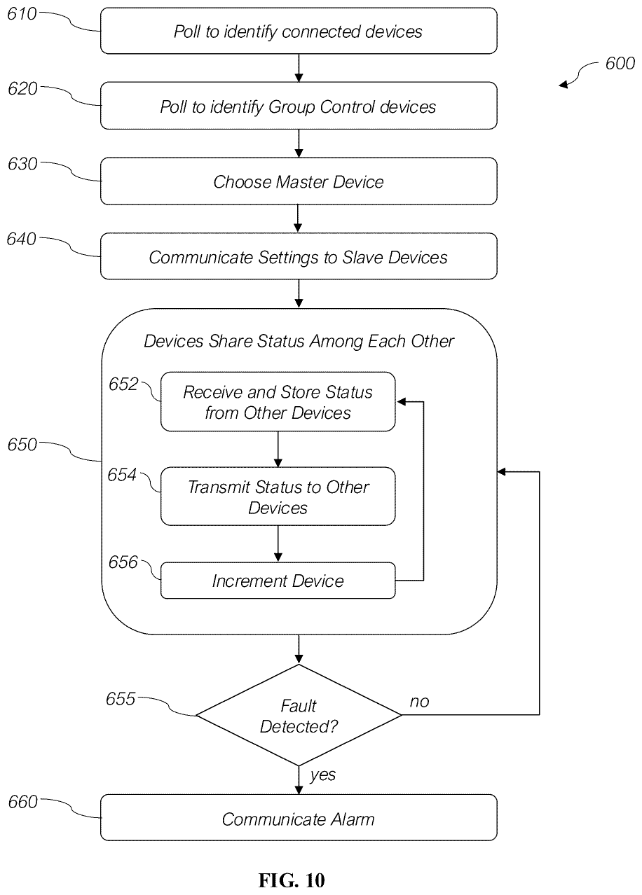

Although the coolant-distribution unit 100 of the heat-transfer system 200 is described as incorporating a liquid-to-liquid heat exchanger (analogous to heat exchanger 105 in FIG. 4), other embodiments of in-row coolant-distribution units lack an internal heat exchanger. Further, the heat-transfer system 200 is described as having a central pump (analogous to pump 110) for the SFN 210, but other embodiments of modular heat-transfer systems have no central pump 110 and instead incorporate a plurality of pumps distributed among the rack-cooling nodes 51 (e.g., an on-rack pump that may be in an intermediary coolant-distribution unit as above or separately in line between the SFN 210 and each node 51 shown in FIG. 5) and/or among the server-cooling nodes (not shown but analogous to the server-cooling nodes 12a-n) within the plurality of the rack-cooling nodes 51, or a combination thereof. In such embodiments, the controller 250 enjoys additional degrees of freedom to tailor cooling capacity through each rack-cooling node 51 and/or server-cooling node therein. That is to say, the controller 250 can adjust a speed or operating point of one or more distributed pumps (e.g., as a group or independently) to tailor the degree of cooling provided by each cooling node 51 in the heat-transfer system. Group control processes described below in context of a modular coolant-distribution unit and FIG. 10 can similarly be applied by the controller 250 to control such distributed pumps, particularly but not exclusively when the pumps are distributed among, for example, a plurality of coolant-distribution modules installed or combined together for operating in concert as a modular coolant-distribution unit.

### V. Modular In-Row CDU

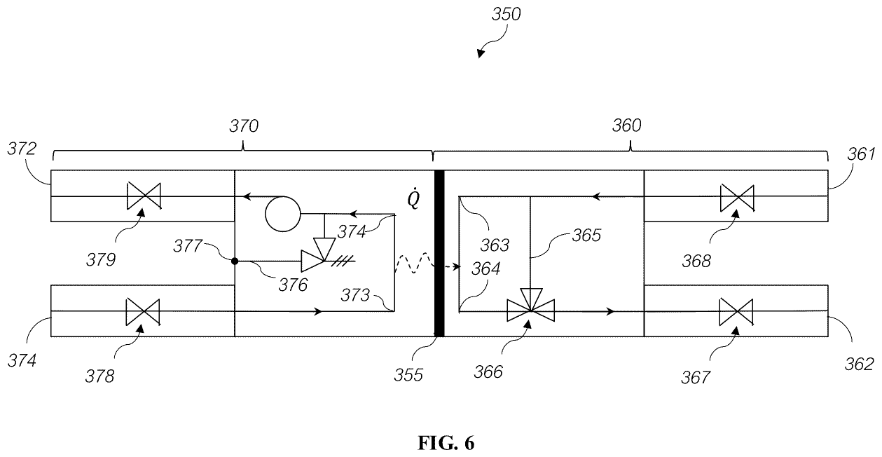

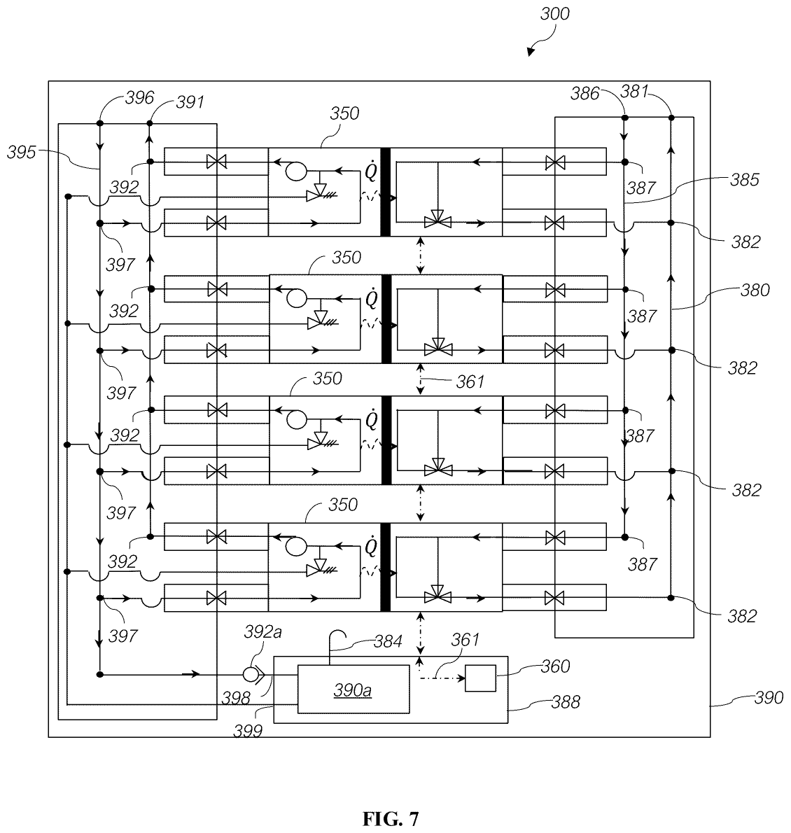

Referring now to FIGS. 6 to 9, embodiments of modular coolant-distribution units are shown and described. A modular coolant-distribution unit provides means for transferring heat from a secondary coolant heated by a plurality of cooling nodes to a primary coolant available from a given facility or other cooling system (or vice-versa, in a heating application), while also providing a scalable heat-transfer capacity. The heat-transfer capacity of a modular coolant-distribution unit can scale (e.g., increase or decrease) according to the heat-transfer rate achievable by each coolant-distribution module installed or installable in the modular coolant-distribution unit, as well as the number of such coolant-distribution modules combined or operated in harmony with each other as a modular coolant-distribution unit. For example, the modular coolant-distribution unit 300 shown in FIG. 7 can have one or more installable and removable coolant-distribution modules 350 (FIG. 6), one or more of which has aspects in common with the coolant-distribution module 100 shown and described in connection with FIGS. 4 and 5. Moreover, the modular coolant-distribution unit 300 can be substituted for the in-row coolant distribution unit 100 described in connection with FIG. 5. When the modular coolant-distribution unit 300 incorporates a plurality of coolant-distribution modules 350 interconnected with each other (e.g., in parallel with each other as in FIG. 7), a controller 360 can adjust operation of each coolant-distribution module 350 in concert with the others so the plurality of coolant-distribution modules function as though there were a single, larger-capacity (relative to each coolant-distribution module 350) coolant-distribution unit 300.

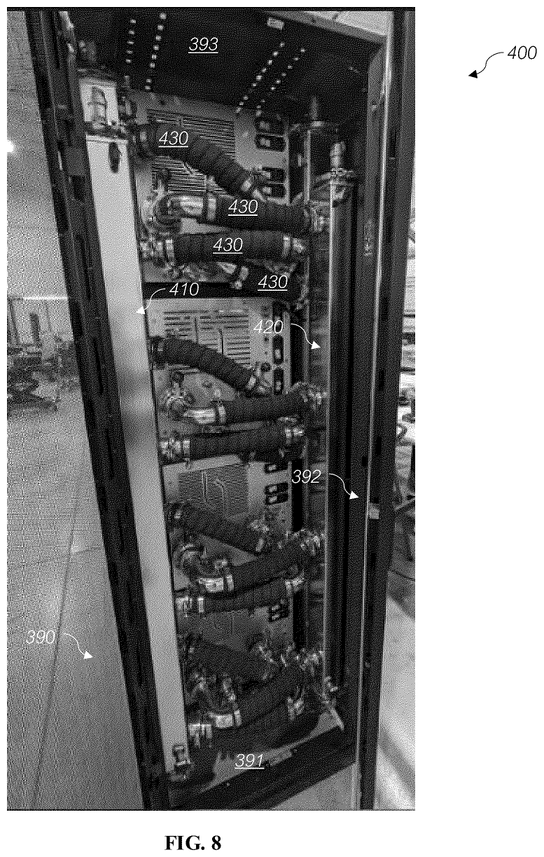

With regard to cooling systems as shown in FIG. 5, the coolant-distribution unit 100 can be embodied as a modular coolant-distribution unit 300 as in FIG. 7. Accordingly, the cooling capacity of the coolant-distribution unit shown in FIG. 5 can scale according to the combined heat-generation load of the various server-cooling nodes 51 it is called upon to cool simply by installing or removing individual coolant-distribution modules 350, as described below. FIG. 8 shows a working embodiment 400 of such a modular coolant-distribution unit.

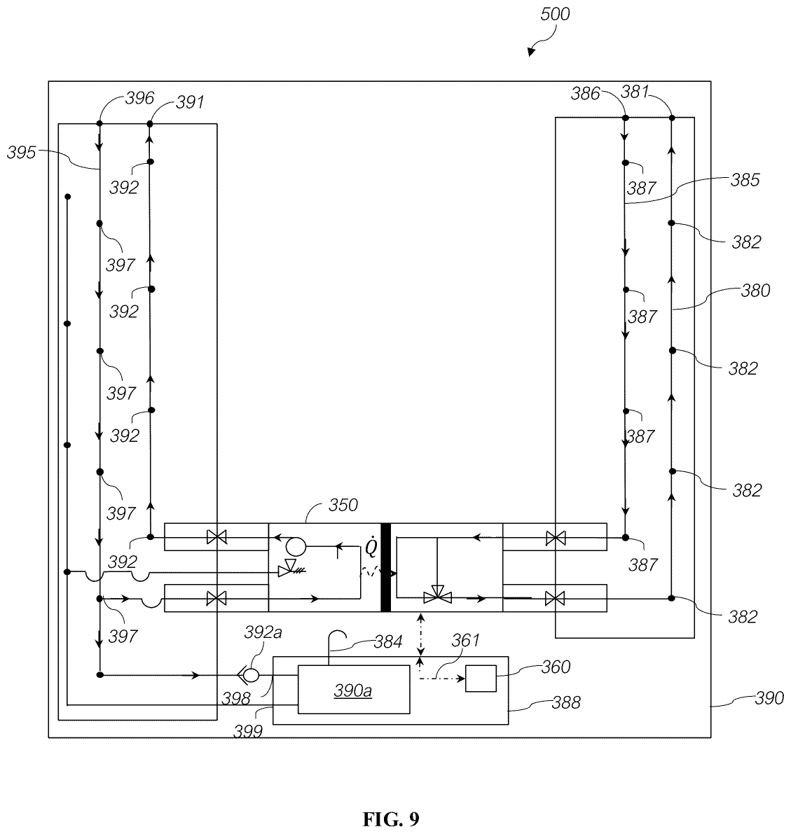

Referring again to FIG. 7, the modular coolant-distribution unit 300 has installed therein a plurality of coolant-distribution modules 350, each being analogous in some respect to the coolant-distribution unit 100 shown and described in connection with FIGS. 4 and 5. The modular coolant-distribution unit 300 shown in FIG. 7 is shown as being fully populated with four coolant-distribution modules 350, though, other embodiments of modular coolant-distribution units can accommodate (and may at any time have installed therein) more or fewer coolant-distribution modules 350. For example, some modular coolant-distribution units can accept one, two, three, five, six, seven, eight, nine, ten, or more, coolant-distribution modules 350. FIG. 8 shows a working embodiment of a modular coolant-distribution unit 400 having four coolant-distribution modules. FIG. 9 schematically illustrates a modular coolant-distribution unit 500, like the modular coolant-distribution unit 300, but having just one coolant-distribution module 350 installed, leaving three remaining bays open to receive up to three additional coolant-distribution modules 350.

Referring again to FIGS. 6 and 7, each coolant-distribution module 350 has a PFN side 360 and an SFN side 370 (like the coolant-distribution module 100 shown in FIG. 4), thermally coupled with each other by a liquid-to-liquid heat exchanger 355. The SFN side 370 defines a segment of the SFN extending from the secondary-coolant return 371 (e.g., an inlet to receive heated secondary coolant) to the secondary-coolant supply 372 (e.g., an outlet to provide cool secondary coolant). A conduit couples the secondary-coolant return 371 with a warm-return (or inlet) 373 to the SFN side of the liquid-to-liquid heat exchanger 355. Another conduit couples the cool-supply (or outlet) 374 from the SFN side of the liquid-to-liquid heat exchanger 355 with an inlet to a pump 375. An outlet of the pump 375 is fluidicly coupled with the secondary-coolant supply 372 of the coolant-distribution module 350.

As well, the inlet side of the pump 375 can be fluidicly coupled with a reservoir conduit 376. The reservoir conduit 376 can include a pressure-relief valve positioned intermediate between the inlet side of the pump 375 and an external reservoir connection 377 (which, as described more fully below, can be coupled with a reservoir 390a to make-up for expansion, contraction, gain, or loss, of secondary coolant).

Each external connection 371, 372, 377 to the SFN side of the coolant-distribution module 350 can have a gate or other valve 378, 379 to inhibit or prevent leakage of the secondary coolant when installing or removing the coolant-distribution module 350 from the modular coolant-distribution unit 300. Moreover, one or more of the valves 378, 379 can be machine controllable by a controller (described below) to modulate, adjust, or otherwise control a flow rate of secondary coolant passing to and from the coolant-distribution module 350, e.g., in conjunction with or independently of controlling a speed of the pump 375.

Referring still to FIG. 6, the PFN side 360 of the coolant-distribution module 350 defines a segment of the PFN extending from the primary-coolant supply 361 (e.g., an inlet to receive cool primary coolant) to the primary-coolant return 362 (e.g., an outlet to return warm primary coolant). A conduit couples the primary-coolant supply 361 with a cool-supply (or inlet) 363 to the PFN side of the liquid-to-liquid heat exchanger 355. Another conduit couples the warm-return (or outlet) 364 from the PFN side of the liquid-to-liquid heat exchanger 355 with the primary-coolant return 362 of the coolant-distribution module 350. A bypass conduit 365 extends from the primary-coolant supply to the primary-coolant return. A three-way mixing valve 366 can provide adjustable control of the flow rate of primary coolant passing through the PFN side 360 of the liquid-to-liquid heat exchanger 355, which allows an operator to tailor a rate of cooling of the secondary coolant, and thus the temperature of the secondary coolant leaving the liquid-to-liquid heat exchanger.

Each external connection 361, 362 with the PFN side of the coolant-distribution module 350 can have a gate or other valve 367, 368 to inhibit or prevent leakage of the primary coolant when installing or removing the coolant-distribution module 350 from the modular coolant-distribution unit 300. Moreover, one or more of the valves 367, 368 can be machine controllable by a controller (as described below) to modulate, adjust, or otherwise control a flow rate of primary coolant passing to and from the coolant-distribution module 350, e.g., in conjunction with or independently of controlling the mixing valve 366 that controls a flow rate of primary coolant bypassing the liquid-to-liquid heat exchanger 355.

In addition to one or more coolant-distribution modules 350, the modular coolant-distribution unit 300 can incorporate a plurality of manifolds for coupling each coolant-distribution module 350 with any other coolant-distribution modules installed in the modular coolant-distribution unit 300, as well as with the supply and return connections on the PFN and SFN sides of the modular coolant-distribution unit 350. For example, FIG. 7 schematically illustrates PFN-side manifolds 380, 385 and SFN-side manifolds 390, 395.

More particularly, the modular coolant-distribution unit 300 has a PFN supply manifold 385 and a PFN return manifold 380. The PFN supply manifold 385 is configured to receive a supply of cool, primary coolant at a PFN supply connection 386 and to distribute the primary coolant among a plurality of coolant-distribution modules 350. Stated differently, the PFN supply manifold has an inlet connection 386 configured to receive primary coolant and a plurality of outlets 387 configured to couple with a PFN-inlet 361 to each coolant-distribution module 350. The PFN return manifold 380 is configured to collect heated primary coolant from among the plurality of coolant-distribution modules 350 and to convey the heated primary coolant to a PFN return connection 381. Stated differently, the PFN return manifold has a plurality of inlet connections 382 configured to receive heated primary coolant from each coolant-distribution module 350 and to convey the heated primary coolant to an outlet, or PFN-return connection 381. Although the PFN connections 381, 386 are shown being positioned at or near the upper extent of the respective PFN manifold 380, 385, the PFN connections 381, 386 can be positioned at any preferred position. For example, connections at or near the top of the PFN manifolds 380, 385 can be convenient when the PFN for a given data center is installed in or near the ceiling of the data center. Alternatively, connections at or near the bottom of the PFN manifolds 380, 385 can be convenient when the PFN for a given data center is installed in or near the floor of the data center.

Similarly, the modular coolant-distribution unit 350 has an SFN supply manifold 390 and an SFN return manifold 395. The SFN supply manifold 390 is configured to deliver a supply of cool, secondary coolant to a SFN supply connection 391 (e.g., an outlet) and to receive cool secondary coolant from among the plurality of coolant-distribution modules 350. Stated differently, the SFN supply manifold has an outlet connection 391 configured to deliver cool secondary coolant to an SFN and a plurality of inlets 392 configured to couple with an SFN-outlet 372 from each coolant-distribution module 350. The SFN return manifold 395 is configured to receive heated secondary coolant from an SFN return connection (an inlet) 396 and to distribute heated secondary coolant among the plurality of coolant-distribution modules 350. Stated differently, the SFN return manifold has an inlet connection 396 configured to receive heated secondary coolant from the SFN and to distribute the heated secondary coolant among a plurality of outlet connections 397, each of which is coupled with the SFN return connection 371 of a coolant-distribution module 350. Although the SFN connections 391, 396 are shown being positioned at or near the upper extent of the respective SFN manifold 390, 395, the SFN connections 391, 396 can be positioned at any preferred position. For example, connections at or near the top of the SFN manifolds 390, 395 can be convenient when the SFN for a given data center is installed in or near the ceiling of the data center. Alternatively, connections at or near the bottom of the SFN manifolds 390, 395 can be convenient when the SFN for a given data center is installed in or near the floor of the data center.

The SFN return manifold 395 can also couple with a reservoir 390a. More particularly, an inlet 381 to the reservoir can be fluidicly coupled in parallel with the SFN-return (inlet) 371 of each in the plurality of coolant-distribution modules 350. A check-valve 392a can be positioned upstream of the reservoir inlet 398 to inhibit or prevent backflow of secondary coolant from the reservoir to the inlet 296 to the SFN-return manifold 395. An outlet 399 from the reservoir can be fluidicly coupled with the external reservoir connection 377 (FIG. 6) of each coolant-distribution module 350. The reservoir 390a in FIG. 7 also includes a vent 384 or pressure-relief valve. In the embodiment shown in FIG. 7, the reservoir 390a is housed within a reservoir module 388 mounted within a chassis 390. The reservoir module 388 can also house a reservoir pump (not shown). The reservoir pump can urge secondary coolant with sufficient pressure head to flow from the reservoir 390a through the outlet 399 to supply a make-up flow of secondary coolant to each external reservoir connection 377 (FIG. 6) among the coolant-distribution modules 350. In some embodiments, such a pump is positioned internally to the reservoir 390a. In some embodiments, such a pump is positioned externally of the reservoir 390a. In some embodiments, such a pump is positioned intermediate the reservoir 390a and the outlet 399. In some embodiments, such a pump is positioned externally of the reservoir. In some embodiments, the pump is positioned intermediate the SFN return connection 396 (FIG. 6) and the reservoir 390a, e.g., intermediate the SFN return connection 396 and the inlet 398 to the reservoir module 388, or intermediate the inlet 398 and the reservoir 390a. In some embodiments, the pump is positioned intermediate the reservoir 390a and each external reservoir connection 377, e.g., intermediate the reservoir 390a and the outlet 399 from the reservoir module, or intermediate the outlet 399 from the reservoir module 399 and the plurality of outlet connections 397.

FIG. 9 shows a modular coolant-distribution unit 500 as in FIG. 7, but being partly populated, i.e., with a single coolant-distribution module 350, rather than being fully populated with, e.g., four, coolant-distribution modules 350. The modular coolant-distribution unit 500 populated as shown in FIG. 8 can provide approximately one-quarter of the rate of cooling that the modular coolant-distribution unit 300 populated as shown in FIG. 7 can provide. Stated differently, each coolant-distribution module 350 can provide a per-module rate of cooling capacity that is linearly or nearly linearly additive to the cooling capacity of already installed coolant-distribution modules (assuming a sufficient supply of cool primary coolant is available from the PFN). For example, installing a second coolant-distribution module 350 that is configured equivalently to the already-installed coolant-distribution module 350 can approximately double the heat-transfer capacity of the modular coolant-distribution unit 500 configured as shown in FIG. 8, assuming a sufficient capacity of primary coolant remains available to provide both coolant-distribution modules 350 with about the same quality and flow-rate of primary coolant available to the coolant-distribution module 350 shown in FIG. 8.

The modular coolant-distribution units 300, 500 shown in FIGS. 7 and 9 have a chassis 390 (sometimes referred to in the art as a “rack”) for physically supporting the various components described above. For example, the chassis 390 (or rack) can provide a plurality of mounting features positioned in correspondence with complementary mounting features defined by each of the various components. FIG. 8 shows, for example, that the rack 390 can have a four-sided (e.g., a rectangular) base 391 supporting a vertical column 392 at or near each corner of the base. The rack 390 can also have a similarly shaped top-plate 393 (or roof). Each vertical column 392 can define a plurality of mounting features dispersed at selected positions along a given face of the respective column. Such mounting features can include one or more holes, rails, studs, brackets, catches, detents, edges, recesses, etc., that are complementary with mounting features defined by one or more of the various components described above. Such complementary mounting features defined by the columns 392 of the rack and the various components can allow technicians to efficiently and quickly install or remove each component. For example, as FIG. 8 shows, an SFN manifold 410 and a PFN manifold 420 can be mounted adjacent opposed columns 392. Similarly, the reservoir can be positioned on or above the base 391 and secured within the rack 390 by mating mounting features of the reservoir with complementary mounting features of the base and/or one or more of the columns. Still further, each coolant-distribution module 350 can be positioned and secured within the rack 390 by mating mounting features of the respective coolant-distribution module 350 with complementary mounting features of one or more of the columns, the reservoir and/or another of the coolant-distribution modules. Once the various components are mounted in or on the rack, the various plumbing connections can be made using conduits 430 extending from one component's connection to a corresponding connection of another component, generally in accordance with the SFN and PFN connections shown and described in relation to, for example, FIG. 6, FIG. 7, and FIG. 9.

The modular coolant-distribution unit shown in FIG. 8 fits within the footprint of a standard 42U server rack, though other embodiments of modular coolant-distribution units can be larger or smaller than a standard 42U server rack, both in terms of footprint and overall height. For example, a “double rack” can be constructed using principles described herein to accommodate, for example, up to two, e.g., side-by-side, vertical stacks of coolant-distribution modules 350, with each vertical stack being analogous to a modular coolant-distribution unit 300. And, although embodiments of modular coolant-distribution units have been described in relation to single-rack embodiments (e.g., as in FIG. 6, or as in a “double rack” embodiment), some modular coolant-distribution units are assembled from a plurality of rack-based coolant-distribution units, each containing a plurality of coolant-distribution modules 350.

For example, the modular coolant-distribution unit 300 shown in FIG. 7 can be plumbed together with one or more other such modular coolant-distribution units, such that the combination functions as a single (albeit higher-capacity and larger) modular coolant-distribution unit. In a combined modular coolant-distribution unit based on two modular coolant-distribution units 300 as in FIG. 7, for example, the SFN supply connection 391 of each constituent modular coolant-distribution unit 300 can be fludicly coupled with each other SFN supply connection. Similarly, the SFN return connection 396 of each constituent modular coolant-distribution unit 300 can be fludicly coupled with each other SFN return connection. Further, the PFN supply connections can be fluidcly coupled with each other in and the PFN return connections can be fluidicly coupled with each other. Such a combination of modular coolant-distribution unit 300 can support, for example, an SFN that cools approximately twice as many arrays (or racks) of servers than a single modular coolant-distribution unit 300 as in FIG. 7 can cool alone. Additional modular coolant-distribution units 300 as in FIG. 7 can be similarly added to further expand the overall cooling capacity of the SFN.

U.S. Pat. No. 11,395,443, issued Jul. 19, 2022, the contents of which are hereby incorporated by reference in their entirety as if recited in full herein, for all purposes, disclosed hot-swappable pumps that can be installed in and removed from a coolant-distribution unit. Such installation and removal is facilitated, in part, by use of blindly-matable quick-disconnect fluid couplers. Some embodiments of presently disclosed coolant-distribution modules 350 can accommodate hot-swappable pumps and pump trays as disclosed in the '443 patent. Further, some embodiments of presently disclosed coolant-distribution modules 350 incorporate alignment features and blindly matable quick-disconnect couplers for each SFN and PFN connection, allowing such embodiments of presently disclosed coolant-distribution modules 350 to be hot-swappable to and from a disclosed modular coolant-distribution unit described above. For example, a modular coolant-distribution unit 300 as in FIG. 7 can define one chassis bay corresponding to each coolant-distribution module 350, as well as a blindly-matable fluid coupler corresponding to each SFN and PFN connection between the coolant-distribution module 350 and the SFN manifolds and the PFN manifolds, respectively. As well, each coolant-distribution module 350 can define a complementary blindly-matable fluid coupler corresponding to each blindly-matable fluid coupler defined by the modular coolant-distribution unit for each SFN and PFN connection. Each bay and each coolant-distribution module 350 can also include complementary, blindly-matable electrical connectors to provide power, ground and communication connections between the coolant-distribution module and the power supply and control system of the modular coolant-distribution unit. Still further, each coolant-distribution module 350 can define complementary alignment features configured to align the coolant-distribution module within each respective chassis bay defined by the modular coolant-distribution unit to ensure the various electrical and fluid connectors matingly engage with each other to open electrical and fluid connections between the coolant-distribution unit and the rest of the modular coolant-distribution unit.

### VI. Group Control of Coolant-Distribution Modules

As described above, coolant-distribution modules 350 can be added to or removed from a modular coolant-distribution unit 300, 500 to adjust, for example, the mass-flow rate, temperature, or both, of secondary coolant flowing through the SFN to match the cooling capacity of the SFN to the rate of heating by the heat sources to be cooled by the various cooling nodes. Referring again to FIGS. 7 and 9, a modular coolant-distribution unit can include control logic 360 configured to control each coolant-distribution module 350 independently of the other coolant-distribution modules, as well as to control the coolant-distribution modules as a group, e.g., so they operate in conjunction with each other as though there are a single coolant-distribution unit. Generally, each coolant-distribution module within or among a group that desirably operates as a single coolant-distribution module can be operated to ensure at least one of the following parameters remains uniform (within defined ranges of variation) across the group: (1) differential pressure supplied across each module's respective SFN supply and return connections; (2) a selected target temperature, e.g., of a return of secondary coolant, a supply of secondary coolant, a return of primary coolant or a supply of primary coolant; and (3) a pump speed.

For example, when a differential pressure or a target temperature is selected as the governing parameter for group control, each coolant-distribution module's corresponding differential pressure or target temperature can be monitored and compared to the differential pressure or target temperature observed or provided by the other coolant-distribution modules. If one coolant-distribution module's differential pressure or target temperature falls outside an acceptable, predefined range, operation of the remaining coolant-distribution modules can be adjusted (e.g., the output of secondary coolant can be increased or decreased) to account for the out-of-range operation. Additionally, an alarm or other communication can be transmitted to alert a technician to a possible operation anomaly. Remedy of an anomaly can be had by hot-swapping, for example, the out-of-range coolant-distribution module, as described elsewhere herein.

As an alternative example, a pump speed can be used as the parameter to provide group operation of a plurality of coolant-distribution modules. In such an embodiment, for example, the speed at which the pump in a selected master coolant-distribution module can be used to establish the pump speed for the other (e.g., slave) coolant-distribution modules. For example, if a differential pressure for the master coolant-distribution module is set to a given value, the pump(s) of the master coolant-distribution module may run at a corresponding speed (e.g., 50% of its maximum speed). When pump speed is used as the control parameter for group mode, the pumps in the other coolant-distribution modules can be set to run at the same speed as the master coolant-distribution module's pump speed (in the illustrative example, 50%).

In some embodiments, a coolant-distribution module (e.g., coolant-distribution module 350) provides a user interface that allows a user to configure one or more operating parameters that the control-logic incorporates in its control of the coolant-distribution module. For example, a user can configure the coolant-distribution module to operate independently or in group mode. When group mode is selected, the operating parameter on which group control is based (e.g., pressure, temperature or speed) can be selected. Further, a user can select one among several coolant-distribution modules to be a master. In some embodiments, the remaining coolant-distribution modules configured as part of a group control can be automatically configured as slaves.

FIG. 10 shows a process 600 for selectively controlling a plurality of coolant-distribution modules 350 as a group when they are communicatively coupled with a logic bus. At 610, a polling inquiry can be transmitted over the logic bus to identify devices connected with the logic bus. For example, each device can have a unique device address and can correspond to a distinct coolant-distribution module 350. Moreover, each device can have one or more device settings stored thereon. For example, such device settings can include technical information pertaining to the pump's operation (e.g., a pump-performance curve), technical information pertaining to the liquid-to-liquid heat exchanger (e.g., head-loss at various flow rates through the SFN side and/or the PFN side, effective heat-transfer coefficients at various flow rates of various fluids through the SFN side and the PFN side), as well as other information, e.g., the total time of operating service that has accumulated on the coolant-distribution module, or whether the coolant-distribution module has been set to individual or group control. At 620, a polling inquiry can be transmitted over the logic bus to identify devices that have been or need to be set to Group Control. At 630, a Master Device is selected. At 640, the settings of the Master Device (or settings from another source or data store) can be communicated to the other devices, e.g., the Slave Devices. During Group Control operation of the modular coolant-distribution unit, the various devices can share their status over the logic bus among each other, at 650. For example, a selected device can receive and store the status received from the other Group Control devices connected with the logic bus, at 652. As well, the selected device can transmit its status to the other Group Control devices, at 654. The control logic can increment the device address to select another Group Control device, at 656. At each increment, the status-sharing process 650 can be repeated. After each device communicates its status to the other Group Control devices, the process can check whether an operation or other fault has been detected, at 655. If not, the device-sharing process 650 repeats. If a fault has been detected, an alarm can be communicated, at 660. For example, such an alarm can include an alarm signal that causes an e-mail to be sent to a technician (e.g., an e-mail containing one or more of the following information: identification information for the data center, the coolant-distribution unit, the type of alarm, historical operation logs, contact information for a system administrator), that causes an audible alarm to sound, that causes a visual fault indicator to illuminate, or that causes another control system to shift a computation load from one or more servers being cooled by the SFN supplied by the modular coolant-distribution unit to another one or more servers being cooled by a different SFN or other cooling system. In still another embodiment, such an alarm can cause one or more valves to close to isolate the coolant-distribution module with the fault from the system, as well as to adjust operation of the remaining coolant-distribution modules under group control to compensate for the loss of the faulty coolant-distribution module. Such isolation and compensation can provide N+1 or other operational redundancy to ensure continuous operational uptime for disclosed module coolant-distribution units.

In some embodiments, one or more sensors can observe a corresponding one or more operational parameters of a module or the system as a whole (e.g., SFN pressures, flow rates, temperatures). A coolant-distribution module (or a modular coolant-distribution unit) can compare sensor outputs to assess a degree of agreement between or among them. If a given sensor's output falls outside an expected range based on one or more other sensors'outputs, a fault can be triggered. Moreover, such information can in some embodiments be displayed on, through, or by a user interface device.

Exemplary operational parameters of the reservoir can include one or more of the following: a coolant level within the reservoir, coolant level within the SFN, on-board vibration, electrical supply and monitoring, pump speed (e.g., a speed of the pump included internally or externally of the reservoir module 388, a speed of one or more pumps in or among the coolant-distribution modules 350, or a combination thereof), differential pressure output by each coolant-distribution module, pressure within the SFN, and status of leak sensors. The reservoir can be configured to adjust its operation to compensate for a change in any such operational parameter. For example, the reservoir can be configured to add coolant to the SFN, e.g., when a selected pressure falls below a threshold pressure the reservoir pump can provide make-up coolant to the SFN connections 377. The reservoir's control logic can be configured to configure or reconfigure one or more of the coolant-distribution modules, e.g., responsive to a detected or observed operational parameter. For example, a coolant-distribution module can be isolated or reconfigured based on detection of a failed or a failing pump within the coolant-distribution module.

The process 600 can be implemented in a computing environment. For example, instructions stored in a computer-readable medium can, when executed, cause a general purpose or a special purpose computing environment to carry out the process. For example, the process can be implemented in a control logic 360 shown in FIGS. 7 and 9.

The control logic 360 can be housed within the chassis of the reservoir module 388 or elsewhere in the coolant-distribution rack 390. The control logic can comprise machine-readable media containing instructions that, when executed, cause a processor of, e.g., a computing environment, to perform one or more disclosed methods. Such instructions can be embedded in software, firmware, or hardware. In addition, the control logic can be carried out in a variety of forms of processor or controller, as in software, firmware, or hardware (e.g., an ASIC). A control unit processor may be a special purpose processor such as an application specific integrated circuit (ASIC), a general purpose microprocessor, a field-programmable gate array (FPGA), a digital signal controller, or a set of hardware logic structures (e.g., filters, arithmetic logic units, and dedicated state machines), or can be implemented in a general computing environment as described elsewhere herein.

### VII. A Data-Center Cooling Architecture

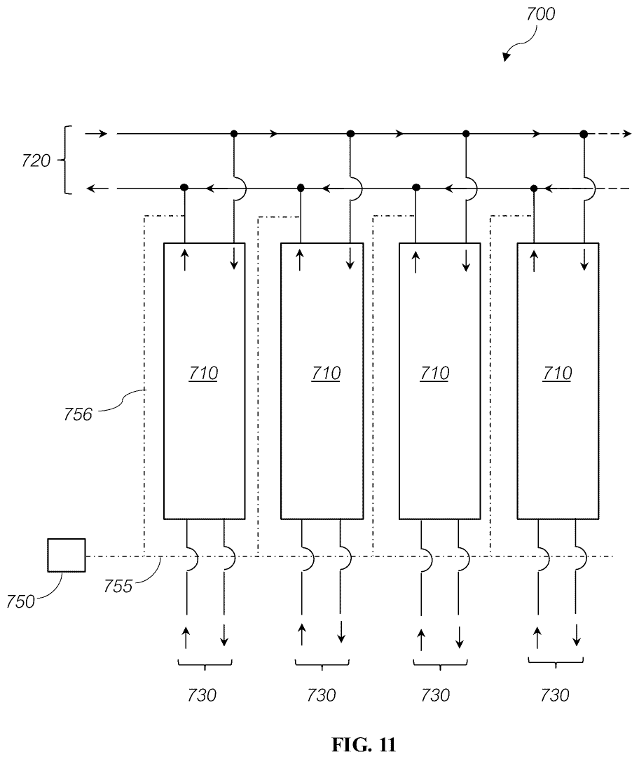

FIG. 11 schematically illustrates a portion of yet another embodiment of a modular heat-transfer system 700. The depiction in FIG. 11 shows four secondary flow network nodes 710 (e.g., each being a modular coolant-distribution unit 300 as described above) coupled with a primary flow network 720. Nevertheless, the system 700 can have more or fewer secondary-flow network nodes 710 coupled with the primary flow network 720.

In FIG. 11, each node 710 corresponds to a distinct coolant distribution unit (e.g., a modular coolant-distribution unit 300) that thermally couples the primary flow network 720 with a respective secondary flow network 730 distributed among and used to cool one or more arrays of rack-mounted servers, as described elsewhere herein, e.g., in connection with FIGS. 7 and 9.

The heat-transfer system 700 also has a controller 750, together with one or more communication connections (e.g., a signal bus 755, 756) that communicatively couple the controller 700 with control logic (e.g., controller 360) in each secondary flow network node 710 (e.g., modular coolant-distribution unit 300). For example, based on information received from one or more sensors, the controller 750 can output a control signal to adjust operation of one or more flow-control devices within or among the PFN 720, SFN 730, and/or any of the secondary flow network nodes 710. As an example of such adjustments, an output signal from the controller 750 can cause a valve to change or to maintain its opening within a range from 0% open (e.g., closed) to 100% open (e.g., unobstructed). As another example, the control output signal can cause a selected pump to speed up, slow down, start, or stop operation. For example, a coolant-distribution unit 300 may have one or more pumps hydraulically coupled with each other in parallel, in series, or a combination of parallel and series to provide suited to maintain stable operation over a wide range of pressure-drop and flow-rate conditions. With such a coolant-distribution unit, the controller can adjust operation of each pump to deliver a target pressure head and flow rate to the corresponding SFN 730. As well, in some embodiments, the control logic 750 includes a gateway for bridging communication from one or more of the SFN nodes 710 with a building management system or other, facility-level control system.

Some embodiments of “smart” modular heat-transfer systems have no central pump for a given PFN 720 or SFN 730, and instead incorporate a plurality of pumps distributed among the SFN 730 and/or PFN 720. In such embodiments, the relevant controller(s) enjoy(s) additional degrees of freedom to tailor cooling capacity through each PFN-or SFN-cooling node. That is to say, the relevant controller(s) can adjust a speed or operating point of one or more distributed pumps (e.g., as a group or independently) to tailor operation of the corresponding components independently or as a group.

### VIII. Computing Environments and Control Logic

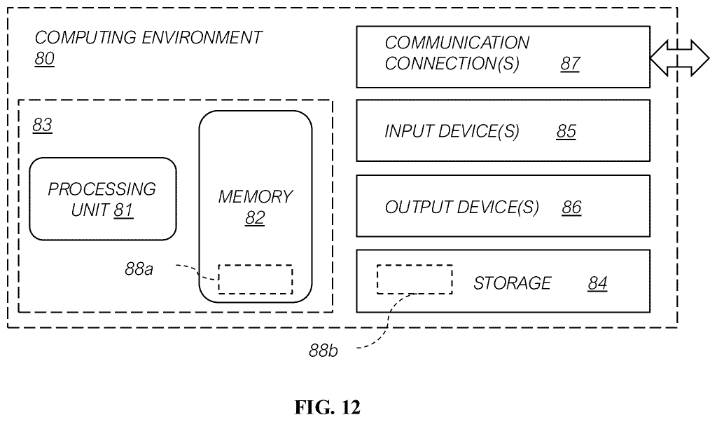

FIG. 12 illustrates a generalized example of a suitable computing environment 80 in which described methods, embodiments, techniques, and technologies relating, for example, to maintaining a temperature of a logic component and/or a power unit below a threshold temperature can be implemented. The computing environment 80 is not intended to suggest any limitation as to scope of use or functionality of the technologies disclosed herein, as each technology may be implemented in diverse general-purpose or special-purpose computing environments. For example, each disclosed technology may be implemented with other computer system configurations, including wearable and/or handheld devices (e.g., a mobile-communications device), multiprocessor systems, microprocessor-based or programmable consumer electronics, embedded platforms, network computers, minicomputers, mainframe computers, smartphones, tablet computers, data centers, servers and server appliances, and the like. Each disclosed technology may also be practiced in distributed computing environments where tasks are performed by remote processing devices that are linked through a communications connection or network. In a distributed computing environment, program modules may be located in both local and remote memory storage devices.

The computing environment 80 includes at least one central processing unit 81 and a memory 82. In FIG. 12, this most basic configuration 83 is included within a dashed line. The central processing unit 81 executes computer-executable instructions and may be a real or a virtual processor. In a multi-processing system, or in a multi-core central processing unit, multiple processing units execute computer-executable instructions (e.g., threads) to increase processing speed and as such, multiple processors can run simultaneously, despite the processing unit 81 being represented by a single functional block. A processing unit can include an application specific integrated circuit (ASIC), a general purpose microprocessor, a field-programmable gate array (FPGA), a digital signal controller, or a set of hardware logic structures arranged to process instructions.

The memory 82 may be volatile memory (e.g., registers, cache, RAM), non-volatile memory (e.g., ROM, EEPROM, flash memory, etc.), or some combination of the two. The memory 82 stores software 88a that can, for example, implement one or more of the technologies described herein, when executed by a processor.

A computing environment may have additional features. For example, the computing environment 80 includes storage 84, one or more input devices 85, one or more output devices 86, and one or more communication connections 87. An interconnection mechanism (not shown) such as a bus, a controller, or a network, interconnects the components of the computing environment 80. Typically, operating system software (not shown) provides an operating environment for other software executing in the computing environment 80, and coordinates activities of the components of the computing environment 80.

The store 84 may be removable or non-removable, and can include selected forms of machine-readable media. In general machine-readable media includes magnetic disks, magnetic tapes or cassettes, non-volatile solid-state memory, CD-ROMs, CD-RWs, DVDs, magnetic tape, optical data storage devices, and carrier waves, or any other machine-readable medium which can be used to store information and which can be accessed within the computing environment 80. The storage 84 can store instructions for the software 88b, which can implement technologies described herein.

The store 84 can also be distributed over a network so that software instructions are stored and executed in a distributed fashion. In other embodiments, some of these operations might be performed by specific hardware components that contain hardwired logic. Those operations might alternatively be performed by any combination of programmed data processing components and fixed hardwired circuit components.

The input device(s) 85 may be any one or more of the following: a touch input device, such as a keyboard, keypad, mouse, pen, touchscreen, touch pad, or trackball; a voice input device, such as a microphone transducer, speech-recognition software and processors; a scanning device; or another device, that provides input to the computing environment 80. For audio, the input device(s) 85 may include a microphone or other transducer (e.g., a sound card or similar device that accepts audio input in analog or digital form), or a computer-readable media reader that provides audio samples to the computing environment 80.

The output device(s) 86 may be any one or more of a display, printer, loudspeaker transducer, DVD-writer, or another device that provides output from the computing environment 80.

The communication connection(s) 87 enable communication over or through a communication medium (e.g., a connecting network) to another computing entity. A communication connection can include a transmitter and a receiver suitable for communicating over a local area network (LAN), a wide area network (WAN) connection, or both. LAN and WAN connections can be facilitated by a wired connection or a wireless connection. If a LAN or a WAN connection is wireless, the communication connection can include one or more antennas or antenna arrays. The communication medium conveys information such as computer-executable instructions, compressed graphics information, processed signal information (including processed audio signals), or other data in a modulated data signal. Examples of communication media for so-called wired connections include fiber-optic cables and copper wires. Communication media for wireless communications can include electromagnetic radiation within one or more selected frequency bands.

Machine-readable media are any available media that can be accessed within a computing environment 80. By way of example, and not limitation, with the computing environment 80, machine-readable media include memory 82, storage 84, communication media (not shown), and combinations of any of the above. Tangible machine-readable (or computer-readable) media exclude transitory signals.

As explained above, some disclosed principles can be embodied in a tangible, non-transitory machine-readable medium (such as microelectronic memory) having stored thereon instructions. The instructions can program one or more data processing components (generically referred to here as a “processor”) to perform a processing operations described above, including estimating, computing, calculating, measuring, adjusting, sensing, measuring, filtering, addition, subtraction, inversion, comparisons, and decision making (such as by the control unit 52). In other embodiments, some of these operations (of a machine process) might be performed by specific electronic hardware components that contain hardwired logic (e.g., dedicated digital filter blocks). Those operations might alternatively be performed by any combination of programmed data processing components and fixed hardwired circuit components.

For sake of brevity throughout this disclosure, computing-environment components, processors, interconnections, features, devices, and media are generally referred to herein, individually, as a “logic component.”

TIA/EIA-485 (sometimes also referred to in the art as “RS-485”) is an electrical standard for interchanging data between or among individual devices (sometimes also referred to as “nodes”). The TIA/EIA-485 standard, in particular, relies on a multipoint, differential-bus architecture. In some respects, disclosed principles provide a multipoint differential bus that allows bi-directional communication between any two selected logic nodes, or devices, connected to the bus. As discussed more fully below, TIA/EIA-485 (RS-485) is a popular electrical standard describing an exemplary embodiment of such a bus suitable for providing one or more communication connections between or among control logic 360 and a controller in each coolant-distribution module 350 (e.g., FIGS. 7 and 9), between controller 250 and controllable valves 240 (e.g., FIG. 5), or between controller 750 and a plurality of modular coolant-distribution units 710 (FIG. 11) having drop connections 756 from a main bus 755. Each drop connection 756 communicatively couples the controller 750 with modular coolant-distribution unit's 710 control logic (e.g., controller 360 (FIG. 7).

As used herein, the term “multipoint-bus” refers to an interconnection medium shared between or among a plurality of devices (or “nodes” or “stations”) that provides a communication connection between or among any selected nodes of the plurality of devices. For example, a multi-point bus can provide three or more stations connected to a common transmission media with the necessary links to communicate data between any selected two nodes. As used herein, a “differential bus” means an interconnection medium that provides for differential signaling.

As used herein, “differential signaling” means an approach for transmitting information or data using a complementary pair of signals. Each in the pair of complementary signals carries the same information and travels on its own electrical conductor (e.g., using a twisted pair of wires, a ribbon cable, or tracks on an interconnect substrate). Electrically, each conductor carries a voltage that is equal in magnitude to that carried by the other conductor but opposite in polarity. A receiver responds to a voltage difference between the complementary signals, which provides a signal having a magnitude twice as large as that of each individual signal, providing a higher signal-to-noise ratio than a single-ended signal. Moreover, radiated emissions from one conductor tend to cancel radiated emissions from the other conductor, reducing interference to signals carried by nearby transmission lines.

Signals can be communicated bidirectionally over a multipoint, differential bus using a full-duplex protocol or a half-duplex protocol. A full-duplex protocol allows transmission and reception of data (e.g., over separate channels, or transmission lines) to occur concurrently.

Referring again to FIGS. 7 and 9, the logic bus 361 includes a primary microcontroller (e.g., controller 360). As well, the microcontroller 360 has transceiver circuitry configured to output differential signals. The transceiver circuitry 315 also is configured to receive differential signal inputs. The reservoir module 388 also includes a suitable electrical connector for coupling the power, ground and signaling connections of the microcontroller's 360 transceiver circuitry with one or more other devices or nodes, e.g., within each coolant-distribution module 350, among components of the reservoir module 388, among other components of the modular coolant-distribution module, and combinations thereof.

Throughout the various drawings, signaling pathways are schematically illustrated with dash-dot-dash lines having double-ended arrows. Each logic node within a given component or cooling node can be communicatively coupled with a further logic node in a “daisy chained” arrangement. As used herein, the term “daisy chained” refers physically serial couplings between or among physical components, e.g., that tend to lengthen a logic bus, notwithstanding that the physical components may include logic nodes (or devices) that have parallel electrically connections to a logic bus. For example, FIG. 7 schematically illustrates a plurality of coolant-distribution modules 350 daisy chained together with a controller 360. By contrast, FIG. 9 schematically illustrates a single coolant-distribution module 350 daisy chained together with the controller 360. Each coolant-distribution module 350 can incorporate an electrical connector suitable for connecting subsequent coolant-distribution modules to the logic bus 361. Further, each coolant-distribution unit can include further cabling to physically extend the logic bus 361 trhough the coolant-distribution module, as well as to provide a drop connection to the control logic device (not shown) within the respective coolant-distribution module 350.

Referring again to FIG. 10, when the primary (or master) device is in a data-receive mode, the microcontrollers of each slave device can be in a data-transmit mode. In this mode, a transmitter in each slave device can emit a signal. The emitted signal can contain the slave device's unique address so the primary microcontroller and other slave devices can identify the source of the incoming information. In some embodiments, one or more transducers in the reservoir module 388, a coolant-distribution module 350, or other system component, can observe one or more characteristics, or parameters, of its environment and communicate a signal containing information pertaining to the observed characteristic to a control logic.

For example, a transducer can be a Hall-effect sensor configured to observe a rotational speed of an electric pump motor. In other embodiments, the transducer 360 can observe an environmental temperature or a barometric pressure, or other relevant system operating parameter, e.g., reservoir fill level, the presence of a liquid suggestive of condensation or a leak. And, although a single transducer has been noted, any selected number of sensor transducers can be added to disclosed logic busses, each of which can output a signal to a control logic, which in turn can digitize the signal and communicate the digitized form of the transducer signal over the logic bus.

Regardless of whether communication occurs using a full-duplex or a half-duplex protocol, each message transmitted by a device can include one or more identifier-bytes (e.g., address-bytes) for identifying the node for which the message is intended. Thus, while all devices on the multi-point bus can receive the message, each device can be programmed to respond only when the received message is addressed to it and/or when a fault is detected (e.g., at 655 in FIG. 10).

A logic bus as described allows the primary microcontroller to control the operation of each node on the bus independently of or in conjunction with the others, as well as to receive and interpret data from each node independently of or in conjunction with the others. It also allows each coolant-distribution module 350 (in FIGS. 7 and 9), each rack-cooling node 51, or each coolant-distribution unit 710 (FIG. 11) to respond to one or more conditions observed by one or more other such modules, units, or nodes. For example, each microcontroller electrically coupled with the bus can communicate with the microcontroller of each other logic node independently of the other microcontrollers connected to the bus, e.g., by transmitting a word (or other digitized signal) that includes a unique address of the targeted microcontroller. Similarly, the microcontroller of each accessory node can communicate with the microcontroller of each of the other accessory nodes and the primary microcontroller independently of each other, as by transmitting a word (or other digitized signal) that includes a unique address of the targeted microcontroller (as well as, in some embodiments, the address of the transmitting microcontroller). Thus, operation of each module, unit or node can be tailored in a selected manner, allowing a plurality of such modules, units or nodes to operation in a coordinated manner that can give rise to the appearance and function of a single, e.g., coolant-distribution unit, despite that it may be based on a combination of a plurality of independently controllable, coolant-distribution modules.

### IX. Other Embodiments

The previous description is provided to enable a person skilled in the art to make or use the disclosed principles. Embodiments other than those described above in detail are contemplated based on the principles disclosed herein, together with any attendant changes in configurations of the respective apparatus or changes in order of method acts described herein, without departing from the spirit or scope of this disclosure. Various modifications to the embodiments and examples described herein will be readily apparent to those skilled in the art.

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper”surface can become a “lower”surface simply by turning the object over. Nevertheless, it is still the same surface and the object remains the same. As used herein, “and/or” means “and” or “or”, as well as “and” and “or.” Moreover, all patent and non-patent literature cited herein is hereby incorporated by reference in its entirety for all purposes.

And, those of ordinary skill in the art will appreciate that the exemplary embodiments disclosed herein can be adapted to various configurations and/or uses without departing from the disclosed principles. Applying the principles disclosed herein, it is possible to provide a wide variety of cooling nodes, and related methods and systems to tailor a cooling system's cooling capacity to an estimated, observed, or anticipated distribution of IT workload (or heat generation). For example, the principles described above in connection with any particular embodiment or example can be combined with the principles described in connection with another embodiment or example described herein. Thus, all structural and functional equivalents to the features and method acts of the various embodiments described throughout the disclosure, and combinations thereof, that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of cooling systems, and related methods and components that can be devised using the various concepts described herein.

Moreover, nothing disclosed herein is intended to be dedicated to the public regardless of whether such disclosure is explicitly recited in the claims. No claim feature is to be construed under the provisions of 35 USC 112(f), unless the feature is expressly recited using the phrase “means for”or “step for”.

The appended claims are not intended to be limited to the embodiments shown herein, but are to be accorded the full scope consistent with the language of the claims, wherein reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, and more particularly but not exclusively in the claims appended hereto.

We currently claim:

1. A modular coolant-distribution unit, comprising:
a manifold configured to distribute a primary coolant among a plurality of primary-coolant supply outlets;
a manifold configured to distribute a secondary coolant among a plurality of secondary-coolant return outlets; and
a plurality of bays, each bay being configured to removably receive a coolant-distribution module configured to fluidicly couple with a selected one or more of the plurality of primary-coolant supply outlets and to fluidicly couple with a selected one or more of the plurality of secondary-coolant return outlets.

2. A modular coolant-distribution unit according to claim 1, further comprising a coolant-distribution module fluidicly coupable with a selected one or more of the plurality of primary-coolant supply outlets and fluidicly coupable with a selected one or more of the plurality of secondary-coolant return outlets, wherein the coolant-distribution module is further configured to thermally couple the primary coolant with the secondary coolant.

3. A modular coolant-distribution unit according to claim 2, wherein the coolant-distribution module further comprises a liquid-to-liquid heat exchanger that thermally couples the primary coolant with the secondary coolant without allowing the primary coolant and the secondary coolant to mix with each other.

4. A modular coolant-distribution unit according to claim 2, wherein the coolant-distribution module is a first coolant-distribution module and the plurality of bays comprises a first bay and a second bay, the modular coolant-distribution unit further comprising a second coolant-distribution module, wherein the first coolant-distribution module and the second coolant-distribution module are removably engageable with the first bay and the second bay, respectively.

5. A modular coolant-distribution unit according to claim 4, wherein the first coolant-distribution module is fluidicly coupable with a selected one or more of the plurality of primary-coolant supply outlets and fluidicly coupable with a selected one or more of the plurality of secondary-coolant return outlets, and wherein the second coolant-distribution module fluidicly coupable with a selected other one or more of the plurality of primary-coolant supply outlets and fluidicly coupable with a selected other one or more of the plurality of secondary-coolant return outlets.

6. A modular coolant-distribution unit according to claim 1, further comprising control logic configured to control operation of a plurality of coolant-distribution modules in concert with each other when the plurality of coolant-distribution modules are fluidicly coupled with a corresponding one or more of the plurality of primary-coolant supply outlets and fluidicly coupled with a corresponding one or more of the plurality of secondary-coolant return outlets.

7. A modular coolant-distribution unit according to claim 6, wherein the logic is configured to harmonize an operational output parameter between or among each of the plurality of coolant-distribution modules.

8. A modular coolant-distribution unit according to claim 7, wherein the operational output parameter comprises one or more of (1) a differential pressure provided to the secondary coolant by each of the plurality of coolant-distribution modules; (2) a speed of a pump corresponding to each of the plurality of coolant-distribution modules; or (3) a selected temperature measure of the primary coolant, the secondary coolant, or both.

9. A modular coolant-distribution unit according to claim 1, further comprising a coolant-distribution module fluidicly coupled with a selected primary-coolant supply outlet and fluidicly coupled with a selected secondary-coolant return outlet, wherein the coolant-distribution module further comprises a liquid-to-liquid heat exchanger that thermally couples the primary coolant with the secondary coolant without allowing the primary coolant and the secondary coolant to mix with each other.

10. A modular coolant-distribution unit according to claim 9, further comprising:
a manifold configured to receive the primary coolant from among a plurality of primary-coolant return inlets; and
a manifold configured to receive the secondary coolant from among a plurality of secondary-coolant supply inlets, wherein the coolant-distribution module is further fluidicly coupled with a selected primary-coolant return inlet and fluidicly coupled with a selected secondary-coolant supply inlet.

11. A modular coolant-distribution unit according to claim 10, wherein the coolant-distribution module is a first coolant-distribution module, the modular coolant-distribution unit further comprising a second coolant-distribution module, wherein the first coolant-distribution module is removably installed in one of the bays and the second coolant-distribution module is removably installed in another one of the bays.

12. A modular coolant-distribution unit according to claim 11, further comprising control logic configured to so control operation of the first coolant-distribution module and the second coolant-distribution module as to harmonize an operational output parameter between the first coolant-distribution module and the second coolant-distribution module.

13. A modular coolant-distribution unit according to claim 12, wherein the first coolant-distribution module comprises a pump configured to urge the secondary coolant through the first coolant-distribution module, wherein the second coolant-distribution module comprises a pump configured to urge the secondary coolant through the second coolant-distribution module, and wherein the operational output parameter comprises one or more of (1) a differential pressure provided to the secondary coolant by each respective coolant-distribution module; (2) a speed of the pump within each of the first coolant-distribution module and the second coolant-distribution module; or (3) a selected temperature measure of the primary coolant, the secondary coolant, or both.

14. A modular coolant-distribution unit according to claim 1, further comprising a chassis so sized as to fit within a row of server racks cooled by the secondary coolant supplied to the server racks by the modular coolant-distribution unit.

15. A modular coolant-distribution unit according to claim 14, wherein the manifold configured to distribute a primary coolant is mounted to the chassis, wherein the manifold configured to distribute the second coolant is mounted to the chassis, and wherein the chassis is configured to mountably support each respective coolant-distribution module removably received by the plurality of bays.

16. A data center, comprising:
a primary fluid network configured to circulate a primary coolant therethrough, the primary fluid network having a plurality of primary coolant-supply connections and a plurality of primary coolant return connections, the primary fluid network comprising a heat exchanger configured to reject heat from a return flow of the primary coolant;
a plurality of modular coolant-distribution units, each modular coolant-distribution unit having a primary coolant supply connection fluidicly coupled with a corresponding primary coolant-supply connection of the primary fluid network, each modular coolant-distribution unit further having a primary coolant return connection fluidicly coupled with a corresponding primary coolant-return connection of the primary fluid network, wherein each modular coolant-distribution unit further comprises:
one or more removably installed coolant-distribution modules configured to operate in concert with one or more other coolant-distribution modules, each coolant-distribution module being configured to transfer heat from a secondary coolant to the primary coolant as the primary coolant and the secondary coolant flow through the respective coolant-distribution module;
a secondary coolant-return manifold configured to convey warm secondary coolant to each of the one or more coolant-distribution modules; and
a secondary coolant-supply manifold configured to receive cool secondary coolant from each of the one or more coolant-distribution modules;
wherein the data center further comprises a secondary fluid network comprising a plurality of rack-cooling nodes, wherein the secondary fluid network receives cool secondary coolant from one or more of the secondary coolant-supply manifolds and wherein the secondary fluid network conveys warm secondary coolant to one or more of the secondary coolant-return manifolds.

17. The data center according to claim 16, wherein each rack-cooling node comprises a plurality of server-cooling nodes.

18. The data center according to claim 17, wherein each server-cooling node comprises at least one component-cooling node, wherein each component-cooling node facilitates a transfer of heat from a heat-generating component to the secondary coolant.

19. The data center according to claim 18, wherein the secondary fluid network conveys the secondary coolant heated by each heat-generating component to the corresponding modular coolant-distribution unit, and wherein the heated secondary coolant rejects heat to the primary coolant flowing through the respective modular coolant-distribution unit.

20. The data center according to claim 19, wherein the heat exchanger of the primary fluid network facilitates rejection, from the primary coolant, of the heat transferred to the primary coolant from the secondary coolant in the modular coolant-distribution unit.
